(19) United States
(12) Patent Application Publication
(10) Pub. No.: US 2026/0209440 A1
(43) Pub. Date: Jul. 23, 2026

(54) RESIN COMPOSITION AND PRODUCT OF THE SAME

(71) Applicant: ELITE ELECTRONIC MATERIAL (ZHONGSHAN) CO., LTD., Zhongshan City (CN)

(72) Inventors: Changyuan LI, Zhongshan City (CN); Teng XU, Zhongshan City (CN); Xiang XIONG, Zhongshan City (CN); Hezong ZHANG, Zhongshan City (CN)

(21) Appl. No.: 19/252,856

(22) Filed: Jun. 27, 2025

(30) Foreign Application Priority Data
Jan. 17, 2025 (CN) 202510080583.1

(51) Int. Cl. C08G 73/12; C08K 5/5399

(52) U.S. Cl. CPC C08G 73/12; C08K 5/5399

(57) ABSTRACT

Disclosed is a resin composition, including 100 parts by weight of a maleimide resin and 10 to 100 parts by weight of a compound of formula (1). Wherein, n is an integer from 3 to 6, X and Y are each independently arylcyclobutenoxy or aryloxy, the number of arylcyclobutenoxy is greater than or equal to 3, and the aryloxy contains or does not contain an alkenyl, an acrylate group or a methacrylate group having 1 to 4 carbon atoms. Further disclosed is a use of the resin composition in preparing a product, and a product of which at least a portion is prepared from the resin composition, wherein the product includes a prepreg, a resin film, a laminate, a printed circuit board, or a cured insulator.

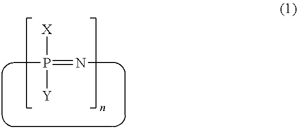

### CROSS-REFERENCE TO RELATED APPLICATIONS

This application claims the priority to Chinese Patent Application No. 202510080583.1, filed to China National Intellectual Property Administration on Jan. 17, 2025, which is incorporated by reference herein in its entirety.

### FIELD

The present application relates to the field of compositions, and more specifically, relates to a resin composition that can be applied to a prepreg, a resin film, a laminate, a printed circuit board, or a cured insulator, and a product thereof.

### BACKGROUND

In recent years, with the popularization and upgrading of electronic products, as well as the rapid development of technologies such as 5G, the Internet of Things, and artificial intelligence, electronic technology is moving towards higher integration, lower power consumption, and higher performance. As electronic basic components, printed circuit boards (PCBs) are widely used in many fields such as mobile phones, computers, mobile communications, data centers, automobiles, industrial control, medical care, and aerospace. Their technical level and reliability have a direct impact on the performance and stability of electronic devices. The performance and reliability of the printed circuit boards largely depend on resin compositions used. In the process of developing a resin composition, on the one hand, it is necessary to continuously pay attention to its conventional characteristics, such as glass transition temperature, copper foil peeling strength and moisture and heat resistance. On the other hand, it is also necessary to observe whether the resin composition produces some defects that affect reliability when processed into products such as printed circuit boards, such as whether resin is sufficiently filled and whether there are gaps at the interface between a resin substrate and a fiberglass fabric. However, how to develop a resin composition having both excellent conventional characteristics and good filling ability and interface adhesion between resin substrate and fiberglass fabric, and a product thereof, is still a goal that needs positive efforts in the art.

### SUMMARY

In view of the problems encountered in the prior art, especially the problem that existing materials cannot meet one or more of the above characteristic requirements, the main objective of the present application is to provide a resin composition that can overcome at least one of the above technical problems, and a product prepared from the resin composition.

The present application provides a resin composition, comprising 100 parts by weight of a maleimide resin and 10 to 100 parts by weight of a compound of formula (1),

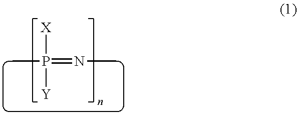

wherein, n is an integer from 3 to 6, X and Y are the same or different, X and Y are each independently arylcyclobutenoxy or aryloxy, the number of arylcyclobutenoxy is greater than or equal to 3, and the aryloxy contains or does not contain an alkenyl, an acrylate group or a methacrylate group having 1 to 4 carbon atoms.

In formula (1), the rounded rectangular ring structure represents a single nitrogen-phosphorus covalent bond connecting the N atom of the final monomer to the P atom of the first monomer.

In one aspect, the present application provides use of the resin composition in preparing a product comprising a prepreg, a resin film, a laminate, a printed circuit board, or a cured insulator.

In one aspect, the present application provides a product, comprising a prepreg, a resin film, a laminate, a printed circuit board, or a cured insulator, wherein, at least a portion of the product is prepared from the resin composition of the present application.

The resin composition or the product thereof provided in some embodiments of the present application can be improved in one or more aspects such as filling ability, interface adhesion between resin substrate and fiberglass fabric, heat resistance after moisture absorption, glass transition temperature, and copper foil peeling strength.

### BRIEF DESCRIPTION OF THE DRAWINGS

FIG. 1 is a photo of a sample of copper-free surface inner-layer circuit laminate, showing shadows presented on the surface, in an embodiment of the present application.

FIG. 2 is a photo of a sample of copper-free surface inner-layer circuit laminate, showing lacking resin on the surface, in an embodiment of the present application.

FIG. 3 is a photo of a sample of copper-free surface inner-layer circuit laminate showing that the filling ability on the surface is normal undertest, in an embodiment of the present application.

FIG. 4 is a photo showing that there are gaps between a resin substrate and a fiberglass fabric, in an embodiment of the present application.

FIG. 5 is a photo showing that the interface adhesion between the resin substrate and the fiberglass fabric is qualified under test, in an embodiment of the present application.

### DETAILED DESCRIPTION

To further elaborate the technical means adopted by the present application to achieve the intended objectives and resulting effects, the specific embodiments, structures, features, and effects based on the present application are described in detail below in conjunction with the accompanying drawings and preferred embodiments.

### Terms and Definitions

The terms used herein (including technical and scientific terms) have the same meanings as those generally understood by technical personnel in the relevant technical field. If otherwise specified, the terms defined herein prevail.

The singular terms used herein refer to one or more. For example, “a component” or “one component” both refer to one or more components. The term “plurality” used herein refers to at least two.

The terms “include”, “comprise”, “comprises”, “comprising”, “contain”, and “have” used herein are all open-ended transitional phrases (which may further include other unlisted elements). The terms “consist of” and “composed of” used herein are both closed transitional phrases.

The numerical range used herein includes all possible sub ranges and all individual values within the range (including fractions and integers).

The term “about” used herein refers to approximation, within a range approximately or nearby. The term “about”, when used in conjunction with a numerical range, modifies the range by expanding the boundary above or below the provided value. Generally speaking, the term “about” used herein varies the numerical value by 10% from the provided value. For example, “about 50%” refers to a range of 45% to 55%. Furthermore, it should be understood that all integers, decimals, and fractions are considered to be modified by the term “about”. The numerical value used herein includes all numerical ranges that are rounded to the nearest significant digit and are the same as this value.

It should be understood that each member of a Markush group can be used solely or in combination to describe the present application. The phrase “or a combination thereof” used herein refers to “or any combination thereof”.

The compounds of the present application may contain asymmetric or chiral centers and therefore exist in different stereoisomeric forms. All stereoisomers of the compounds in the present application, including diastereomers, enantiomers, and atropisomers, as well as mixtures thereof such as racemic mixtures, shall be considered as a portion of the present application, but the present application is not limited thereto.

In structural formulas, “*” represents a bonding site.

The term “polymer” used herein refers to a product formed by polymerization reaction of monomers. The polymer may include homopolymers (a.k.a. autopolymers), copolymers, prepolymers, etc., but the present application is not limited thereto.

The term “homopolymer” used herein refers to a chemical substance formed by polymerization, addition polymerization, and condensation polymerization of a single compound.

The copolymer refers to a chemical substance formed by polymerization, addition polymerization, and condensation polymerization of two or more compounds, including random copolymers (with a structure such as -AABABBBAAABBA-), alternating copolymers (with a structure such as -ABABABAB-), graft copolymers (with a structure such as

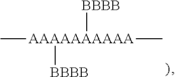

and block copolymers (with a structure such as -AAAAA-BBBBBB-AAAAA-).

The term “prepolymer” used herein refers to a polymer with a lower molecular weight between the molecular weights of a monomer and a final polymer, and the prepolymer contains reactive functional groups that can be further polymerized to obtain a fully cross-linked or hardened higher molecular weight product.

The polymer also includes oligomers, but the present application is not limited thereto. The oligomers, a.k.a. low polymers, are polymers composed of 2 to 20 repeat units, generally 2 to 5 repeat units.

The “modifier” used herein includes products modified by reactive functional groups of each resin, products of pre-polymerization between each resin and other resins, products of cross-linking between each resin and other resins, products of homopolymerization of each resin, products of copolymerization between each resin and other resins, and the like. For example, modification may be achieved by substituting vinyl for original hydroxyl through a chemical reaction, or by reacting original terminal vinyl with p-aminophenol to obtain terminal hydroxyl, but the present application is not limited thereto.

Various alkyls, various alkenyls, and various hydrocarbyls used herein should include their various isomers. For example, the term “propyl” used herein includes both n-propyl and isopropyl.

The “aryl” referred to in the present application refers to unsaturated aromatic carbon rings with 6 to 30 carbon atoms and a single ring (such as phenyl) or a plurality of fused rings (such as naphthyl or anthryl), preferably with 6 to 18 carbon atoms, and more preferably with 6 to 12 carbon atoms. Preferred aryls include phenyl, biphenyl, naphthyl, etc.

The “resin” used herein may include monomers, polymers thereof, combinations of monomers, combinations of polymers thereof, or combinations of monomers and polymers thereof, etc., but the present application is not limited thereto. For example, the “maleimide resin” includes at least maleimide monomers (small molecular maleimide compounds), maleimide polymers, combinations of maleimide monomers, combinations of maleimide polymers, and combinations of maleimide monomers and maleimide polymers.

The “resin substrate” used herein refers to a cured form of a resin composition after sufficient curing, not including non-resin composition portions such as conductor layers and reinforcing materials. For example, copper-clad laminates include cured resin compositions, fiberglass fabrics, and copper foils, wherein, the cured resin compositions are resin substrates, excluding fiberglass fabrics and copper foils.

The “polyfunctional” used herein refers to two or more functional groups included in molecules (especially monomers of polymers). For example, “polyfunctional maleimide” includes two or more maleimide functional groups; “polyfunctional amine” includes two or more amino groups; and “polyfunctional phenol” include two or more phenolic hydroxyl groups.

The parts by weight used herein represent the number of parts of weight, which can be any weight unit, such as kilograms, grams, or pounds, but the present application is not limited thereto. For example, 100 parts by weight of maleimide resin may represents 100 kilograms of maleimide resin or 100 pounds of maleimide resin.

The term “wt %” used herein represents weight percentage.

### Embodiments of the Present Application

### Resin Composition

The present application provides a resin composition, comprising 100 parts by weight of a maleimide resin and 10 to 100 parts by weight of a compound of formula (1).

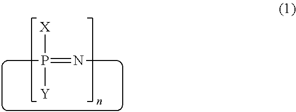

wherein, n is an integer from 3 to 6, X and Y are the same or different, X and Y are each independently arylcyclobutenoxy or aryloxy, the number of arylcyclobutenoxy is greater than or equal to 3, and the aryloxy contains or does not contain an alkenyl, an acrylate group or a methacrylate group having 1 to 4 carbon atoms.

### Maleimide Resin

In some exemplary embodiments, the maleimide resin may comprise compounds or mixtures with one or more maleimide functional groups in molecules. The maleimide resin used in the present application may be any one or more maleimide resins used for preparing a prepreg, a resin film, a laminate, a printed circuit board, or a cured insulator, but the present application is not limited thereto.

Specific examples of the maleimide resin may comprise 4,4′-diphenylmethane bismaleimide, phenylmethane bismaleimide oligomer, biphenylaralkyl type bismaleimide, indane-containing bismaleimide, m-phenylene bismaleimide, bisphenol A diphenyl ether bismaleimide, 3,3′-dimethyl-5,5′-diethyl-4,4′-diphenylmethane bismaleimide, 4-methyl-1,3-phenylene bismaleimide, 1,6-bismaleimido(2,2,4-trimethyl)hexane, 2,3-dimethylphenylmaleimide, 2,6-dimethylphenylmaleimide, N-phenylmaleimide, maleimide resin containing an aliphatic long chain structure, or a combination thereof, but the present application is not limited thereto.

In some exemplary embodiments, the maleimide resin may be any one or more maleimide resin prepolymers with one or more maleimide functional groups in molecules used for preparing a prepreg, a resin film, a laminate, a printed circuit board, or a cured insulator. The maleimide resin may comprise prepolymers of diallyl compounds and maleimide resin, prepolymers of polyfunctional amines and maleimide resin, prepolymers of acidic phenolic compounds and maleimide resin, or a combination thereof, but the present application is not limited thereto.

In some exemplary embodiments, the maleimide resin may be a polyfunctional maleimide resin. The polyfunctional maleimide resin may comprise 4,4′-diphenylmethane bismaleimide, phenylmethane bismaleimide oligomer, biphenylaralkyl type bismaleimide, indane-containing bismaleimide, m-phenylene bismaleimide, bisphenol A diphenyl ether bismaleimide, 3,3′-dimethyl-5,5′-diethyl-4,4′-diphenylmethane bismaleimide, 4-methyl-1,3-phenylene bismaleimide, 1,6-bismaleimido(2,2,4-trimethyl)hexane, polyfunctional maleimide resin containing an aliphatic long chain structure, or a combination thereof, but the present application is not limited thereto.

For example, the maleimide resin may be maleimide resins produced by Daiwakasei Industry Co., Ltd. under the trade names of BMI-1000, BMI-1000H, BMI-1100, BMI-1100H, BMI-2000, BMI-2300, BMI-3000, BMI-3000H, BMI-4000H, BMI-5000, BMI-5100, BMI-7000, BMI-7000H, etc., or maleimide resins fabricated by K.I Chemical Industry Co., Ltd. under the trade names of BMI-70, BMI-80, etc., or maleimide resins produced by Nippon Kayaku Co., Ltd. under the trade names of MIR-3000, etc., or maleimide resins produced by DIC (DaiNippon Ink Chemicals Industry Company) under the trade names of X9-470, NE-X-9470S, or NE-X-9480, or other commercially available indane-containing bismaleimide resins.

For example, the maleimide resin containing an aliphatic long chain structure may be BMI-689, BMI-1400, BMI-1500, BMI-1700, BMI-2500, BMI-3000, BMI-5000, or BMI-6000 maleimide resin produced by Designer Molecules INC. The maleimide resin containing an aliphatic long chain structure may have at least one maleimide functional group connected to a substituted or unsubstituted long-chain aliphatic group. The long-chain aliphatic group may be an aliphatic group with a carbon number from C₅ to C₅₀, such as C₁₀ to C₅₀, C₂₀ to C₅₀, C₃₀ to C₅₀, C₂₀ to C₄₀, or C₃₀ to C₄₀, but the present application is not limited thereto.

For example, examples of commercially available maleimide resins containing long aliphatic chain structures are as follows:

BMI-689:

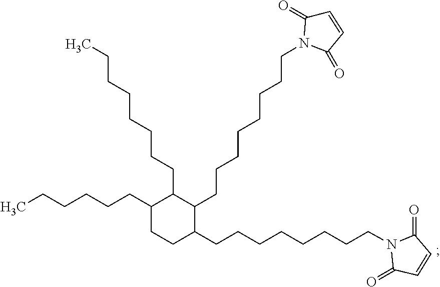 [SMILES: CCCCCCCCC1C(CCCCCC)CCC(CCCCCCCCN2C(=O)C=CC2=O)C1CCCCCCCCN1C(=O)C=CC1=O]

BMI-1400:

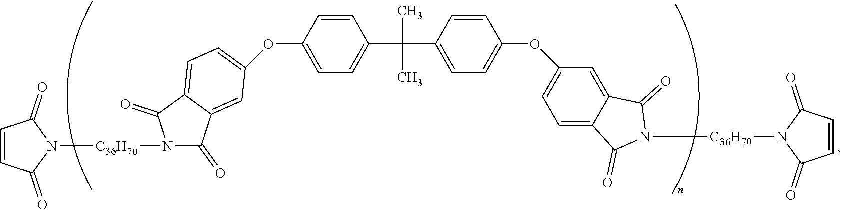

wherein n is 1 to 10;

BMI-1500:

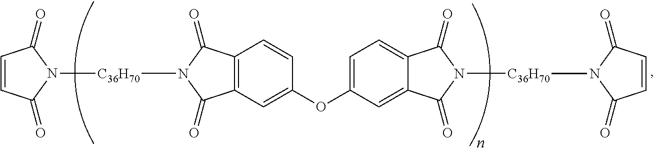

wherein n has an average value of 1.3;

BMI-1700:

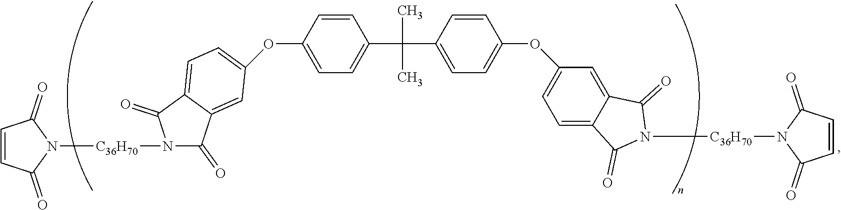

wherein n is 1 to 10;

BMI-2500:

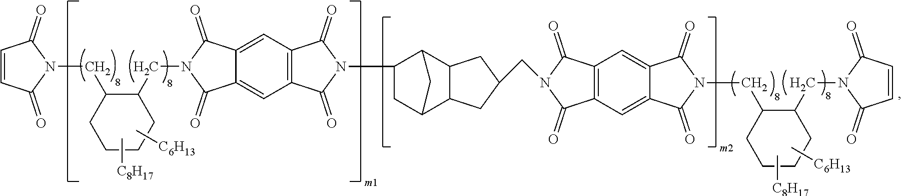

wherein m1 has an average value of 3; m2 has an average value of 3;

BMI-3000, BMI-5000, BMI-6000:

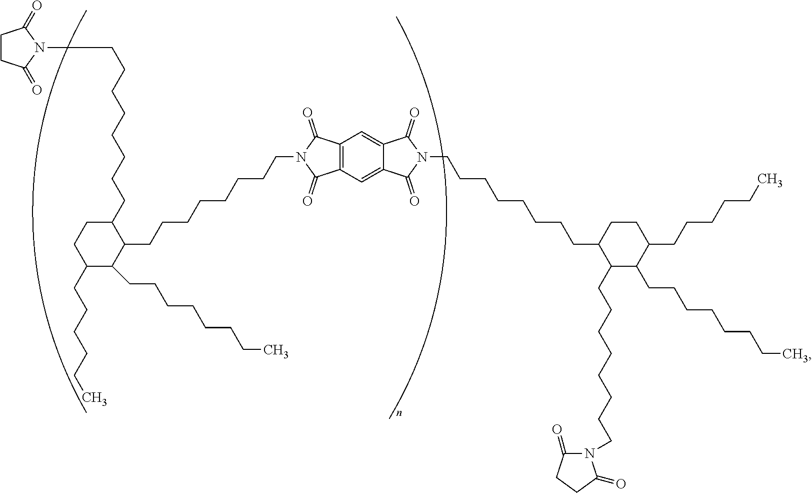

wherein n is 1 to 10.

### Compound of Formula (1)

In some exemplary embodiments, the phosphorus content of the compound of formula (1) is 2.0 wt % to 13.0 wt %, such as 2.3 wt % to 12.7 wt %, 4.0 wt % to 13.0 wt %, 6.0 wt % to 13.0 wt %, 8.0 wt % to 12.7 wt %, 10.0 wt % to 12.7 wt %, or 10.0 wt % to 12.0 wt %.

In some exemplary embodiments, in the compound of formula (1), the aryl in the arylcyclobutenoxy and the aryloxy is each independently substituted or unsubstituted phenyl, biphenyl, or naphthyl. The number of substituents is not limited, and any hydrogen atom on the aromatic ring may be substituted by a substituent. Specific examples of the substituents comprise alkyl having 1 to 10 carbon atoms, alkoxy having 1 to 10 carbon atoms, alkylamino having 1 to 10 carbon atoms, alkylthio having 1 to 10 carbon atoms, aryl with 6 to 13 carbon atoms, benzyl with 6 to 13 carbon atoms, aryloxy with 6 to 13 carbon atoms, or benzyloxy with 6 to 13 carbon atoms, such as methyl, ethyl, propyl, butyl, tert-butyl, pentyl, hexyl, heptyl, octyl, nonyl, decyl, phenyl, benzyl, methoxy, ethoxy, propoxy, butoxy, phenoxy, benzyloxy, dimethylamino, diethylamino, methylthio, or ethylthio, and is not limited thereto. In one exemplary embodiment, the aryls in the arylcyclobutenoxy and the aryloxy in the compound of formula (1) are unsubstituted phenyl, biphenyl, or naphthyl. In another exemplary embodiment, at least one benzene ring of the aryls in the arylcyclobutenoxy and the aryloxy in the compound of formula (1) is substituted by a substituent, and the substituent may be alkyl having 1 to 4 carbon atoms, alkoxy having 1 to 4 carbon atoms, or alkylamino having 1 to 4 carbon atoms. In another exemplary embodiment, at least one benzene ring of the aryls in the arylcyclobutenoxy and the aryloxy in the compound of formula (1) is substituted by a substituent, and the substituent may be alkyl having 1 to 4 carbon atoms.

In some exemplary embodiments, in the compound of formula (1), the structure of the arylcyclobutenoxy is shown in formula (2), and the structure of the aryloxy is shown in formula (3);

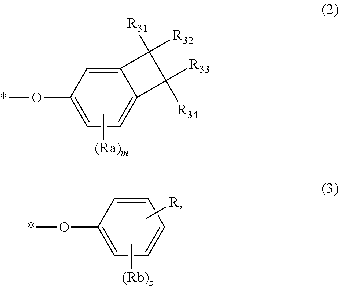

wherein, Ra and Rb are each independently H or alkyl having 1 to 4 carbon atoms, m is an integer from 0 to 3, z is an integer from 0 to 4, R is H or an alkenyl or an acrylate group or a methacrylate group having 1 to 4 carbon atoms, and R₃₁ to R₃₄ are each independently H or hydrocarbyl having 1 to 3 carbon atoms.

In some exemplary embodiments, R is a vinyl, a propenyl, an allyl, an acrylate group, or a methacrylate group, and is located at an ortho-position, meta-position, or para-position of a carbon oxygen bond.

In some exemplary embodiments, in formula (2), at least one of R₃₁ to R₃₄ is methyl, ethyl, or propyl.

In some exemplary embodiments, in formula (2), R₃₁ to R₃₄ are all H.

In some exemplary embodiments, the compound of formula (1) has at least three formulas (2) in X and Y.

For example, when n is 3, and X is formula (2) and Y is formula (3) in the compound of formula (1), when the number of formula (2) is 3, 4, 5, or 6, the number of formula (3) is 3, 2, 1, or 0.

For example, when n is 4, and X is formula (2) and Y is formula (3) in the compound of formula (1), when the number of formula (2) is 3, 4, 5, 6, 7, or 8, the number of formula (3) is 5, 4, 3, 2, 1, or 0.

For example, when n is 5, and X is formula (2) and Y is formula (3) in the compound of formula (1), when the number of formula (2) is 3, 4, 5, 6, 7, 8, 9, or 10, the number of formula (3) is 7, 6, 5, 4, 3, 2, 1, or 0.

For example, when n is 6, and X is formula (2) and Y is formula (3) in the compound of formula (1), when the number of formula (2) is 3, 4, 5, 6, 7, 8, 9, 10, 11 or 12, the number of formula (3) is 9, 8, 7, 6, 5, 4, 3, 2, 1, or 0.

The compound of formula (1) described in the present application comprises various isomers thereof.

In the structure of compound (1), the phosphazene ring formed by phosphorus and nitrogen atoms has flame retardancy, and the arylcyclobutenyl opens its ring at a high temperature or under the action of a photocatalyst to form conjugated diene, which can undergo cross-linking reaction with other resins containing carbon-carbon double bonds. For example, in the system of maleimide resin containing double bonds, the compound of formula (1) can undergo cross-linking reaction with the maleimide resin at a high temperature, which can simultaneously improve one or more effects such as filling ability, interface adhesion between resin substrate and fiberglass fabric, heat resistance after moisture absorption, glass transition temperature, or copper foil peeling strength.

In some exemplary embodiments, when n is 3, for example, the compound of formula (1) may be the structure shown in formula (4), formula (5), formula (6), formula (7), formula (8), formula (9), or formula (10) below:

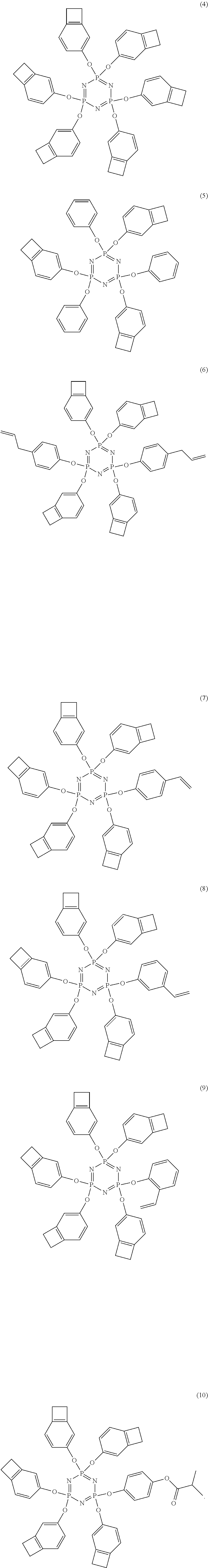

In some exemplary embodiments, when n is 4, for example, the compound of formula (1) may be the structure shown in formula (11), (12), (13), or (14) below:

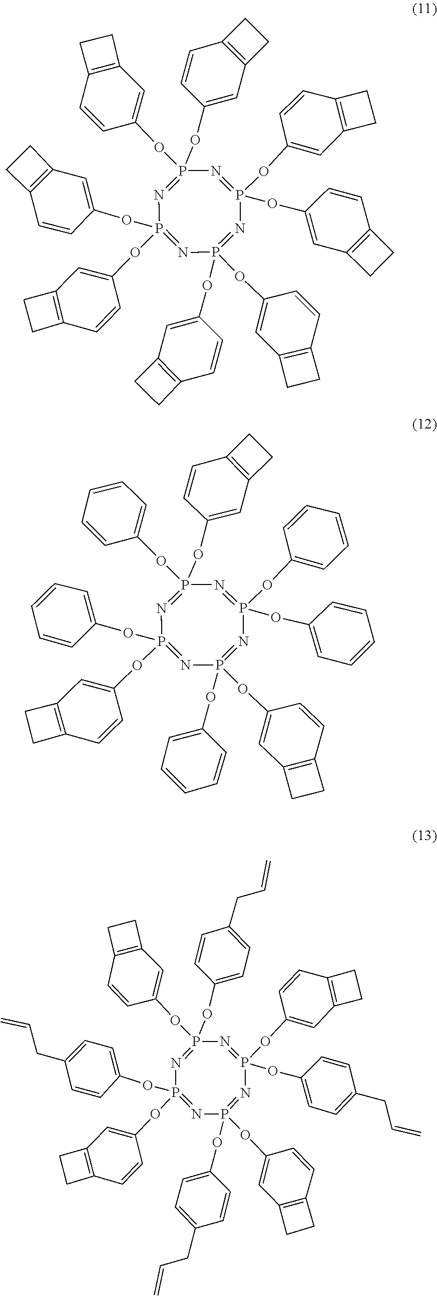 [SMILES: c1cc2c(cc1OP1(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=N1)CC2 ; c1ccc(OP2(Oc3ccccc3)=NP(Oc3ccccc3)(Oc3ccc4c(c3)CC4)=NP(Oc3ccccc3)(Oc3ccc4c(c3)CC4)=NP(Oc3ccccc3)(Oc3ccc4c(c3)CC4)=N2)cc1 ; C=CCc1ccc(OP2(Oc3ccc4c(c3)CC4)=NP(Oc3ccc(CC=C)cc3)(Oc3ccc4c(c3)CC4)=NP(Oc3ccc(CC=C)cc3)(Oc3ccc4c(c3)CC4)=NP(Oc3ccc(CC=C)cc3)(Oc3ccc4c(c3)CC4)=N2)cc1]

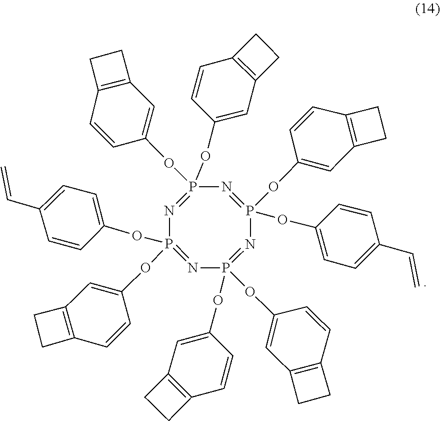 [SMILES: C=Cc1ccc(OP2(Oc3ccc4c(c3)CC4)=NP(Oc3ccc4c(c3)CC4)(Oc3ccc4c(c3)CC4)=NP(Oc3ccc(C=C)cc3)(Oc3ccc4c(c3)CC4)=NP(Oc3ccc4c(c3)CC4)(Oc3ccc4c(c3)CC4)=N2)cc1]

In some exemplary embodiments, when n is 4, for example, the compound of formula (1) may be the structure shown in formula (15), formula (16), formula (17), or formula (18) below:

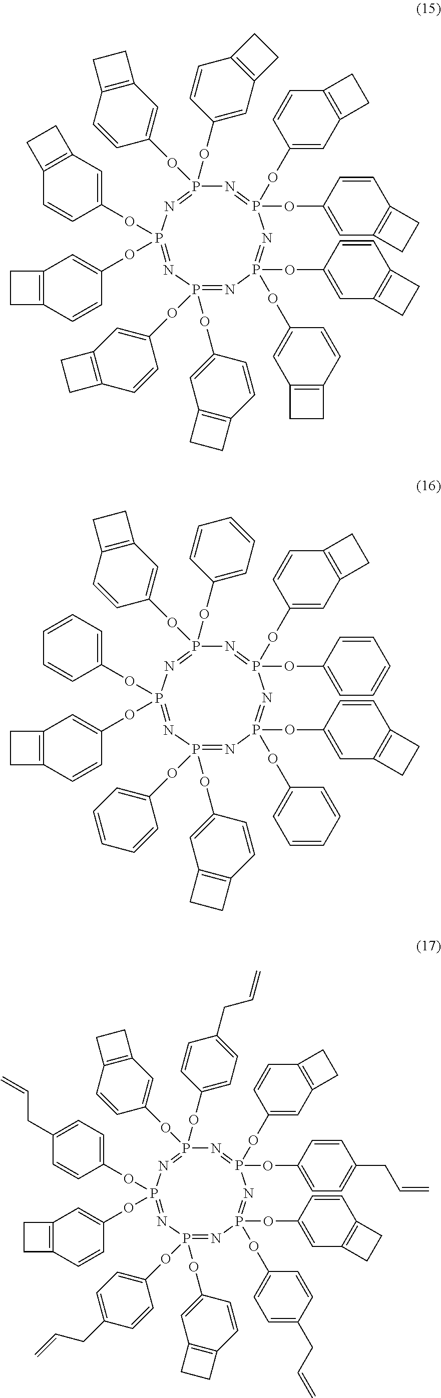

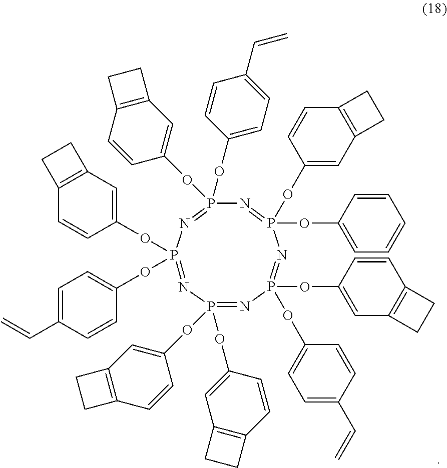 [SMILES: C=Cc1ccc(OP2(Oc3ccc4c(c3)CC4)=NP(Oc3ccc(C=C)cc3)(Oc3ccc4c(c3)CC4)=NP(Oc3ccc4c(c3)CC4)(Oc3ccc4c(c3)CC4)=NP(Oc3ccc(C=C)cc3)(Oc3ccc4c(c3)CC4)=NP(Oc3ccccc3)(Oc3ccc4c(c3)CC4)=N2)cc1]

In some exemplary embodiments, when n is 6, for example, the compound of formula (1) may be the structure shown in formula (19), formula (20), formula (21), or formula (22) below:

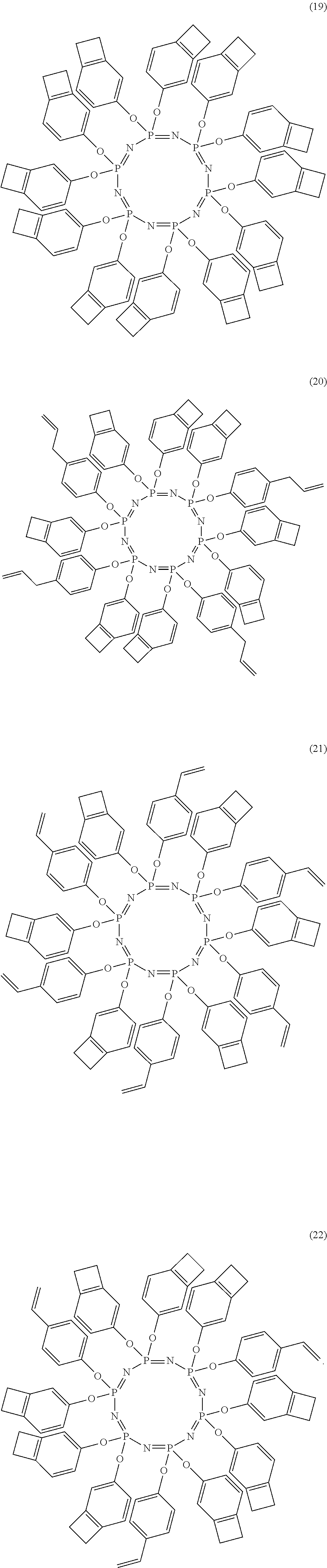

### Optional Ingredients of the Resin Composition

In some exemplary embodiments, the resin composition may further comprise at least one of maleimide triazine resin, small molecular vinyl-containing resin, prepolymer of small molecular vinyl-containing resin, styrene maleic anhydride resin, epoxy resin, phenolic resin, benzoxazine resin, cyanate ester resin, polyester resin, polyamide resin, and polyimide resin.

In some exemplary embodiments, the resin composition comprises a maleimide triazine resin. The maleimide triazine resin may be any one or more maleimide triazine resins used for preparing a prepreg, a resin film, a laminate, a printed circuit board, or a cured insulator. The maleimide triazine resin may be obtained by polymerizing cyanate ester resin with maleimide resin, especially by polymerizing bisphenol A cyanate ester resin with maleimide resin, by polymerizing bisphenol F cyanate ester resin with maleimide resin, by polymerizing phenolic novolac cyanate ester resin with maleimide resin, or by polymerizing dicyclopentadiene-containing cyanate ester resin with maleimide resin. The maleimide triazine resin may be obtained by polymerizing cyanate ester resin with maleimide resin in any molar ratio, especially by polymerizing cyanate ester resin with maleimide resin in a molar ratio of (1-10):1, especially (1-6):1, and more especially 1:1, 2:1, 4:1 or 6:1.

In some exemplary embodiments, the resin composition comprises a small molecular vinyl-containing resin. The small molecular vinyl-containing resin may comprise vinyl compounds with a molecular weight of less than or equal to 1000, especially a molecular weight between 100 and 900, and more preferably a molecular weight between 100 and 800. The small molecular vinyl-containing resin may comprise styrene, divinylbenzene, ethylstyrene, bis(vinylbenzyl)ether, 1,2,4-trivinylcyclohexane (TVCH), bis(vinylphenyl)ethane (BVPE), bis(vinylphenyl)hexane, bis(vinylphenyl) dimethylene ether, bis(vinylphenyl) dimethylenebenzene, triallyl isocyanurate (TAlC), triallyl cyanurate (TAC), or a combination thereof, but the present application is not limited thereto.

In some exemplary embodiments, the resin composition comprises a prepolymer of small molecular vinyl-containing resin. The prepolymer of small molecular vinyl-containing resin may comprise styrene prepolymer, divinylbenzene prepolymer, ethylstyrene prepolymer, bis(vinylbenzyl)ether prepolymer, 1,2,4-triethylcyclohexane prepolymer, bis(vinylphenyl)ethane prepolymer, bis(vinylphenyl)hexane prepolymer, bis(vinylphenyl) dimethylene ether prepolymer, bis(vinylphenyl)dimethylbenzene prepolymer, triallyl isocyanurate prepolymer, triallyl cyanurate prepolymer, or a combination thereof, but the present application is not limited thereto. For example, the styrene prepolymer may represent a styrene content in this prepolymer being greater than or equal to 50 wt %, or a styrene content in the styrene prepolymer between 50 wt % and 99 wt %, while the content of a second monomer unit in the styrene prepolymer being less than or equal to 49 wt %, such as between 1 wt % and 49 wt %. For example, in one exemplary embodiment, the styrene prepolymer comprises 55 wt % to 75 wt % of a styrene monomer unit, 15 wt % to 35 wt % of a divinylbenzene monomer unit, and 5 wt % to 30 wt % of an ethylstyrene monomer unit. In another exemplary embodiment, the divinylbenzene prepolymer comprises 60 wt % of a divinylbenzene monomer unit, 30 wt % of an ethylstyrene monomer unit, and 10 wt % of a styrene monomer unit. In another exemplary embodiment, the ethylstyrene prepolymer comprises 60 wt % of an ethylstyrene monomer unit, 30 wt % of a styrene monomer unit, and 10 wt % of a divinylbenzene monomer unit. For example, the styrene prepolymer may alternatively represent a styrene content greater than or equal to the content of any other monomer. For example, in one exemplary embodiment, the styrene prepolymer comprises 40 wt % of a styrene monomer unit, 30 wt % of a divinylbenzene monomer unit, and 30 wt % of an ethylstyrene monomer unit.

In some exemplary embodiments, the resin composition comprises a styrene maleic anhydride resin. The molar ratio of styrene to maleic anhydride in the styrene maleic anhydride resin may be (1-8):1, such as 1:1, 2:1, 3:1, 4:1, 6:1, or 8:1. The styrene maleic anhydride resin may be a styrene maleic anhydride copolymer. The styrene maleic anhydride copolymer may be styrene maleic anhydride copolymers purchased from Cray Valley Company under the trade names of SMA-1000, SMA-2000, SMA-3000, EF-30, EF-40, EF-60, EF-80, etc., or styrene maleic anhydride copolymers sold by Polyscope Company under the trade names of C400, C500, C700, C900, etc., but the present application is not limited thereto. The styrene maleic anhydride resin may be an esterified styrene maleic anhydride copolymer. The esterified styrene maleic anhydride copolymer may be esterified styrene maleic anhydride copolymers purchased from Cray Valley Company under the trade names of SMA1440, SMA17352, SMA2625, SMA3840, SMA31890, etc., but the present application is not limited thereto. The resin composition may comprise one styrene maleic anhydride resin, or a combination of a plurality of styrene maleic anhydride resins.

In some exemplary embodiments, the resin composition may further comprise an epoxy resin. For example, the epoxy resin may be various types of epoxy resins known in the art, comprising bisphenol A epoxy resin, bisphenol F epoxy resin, bisphenol S epoxy resin, bisphenol AD epoxy resin, novolac epoxy resin (such as polyfunctional novolac epoxy resin), trifunctional epoxy resin, tetrafunctional epoxy resin, dicyclopentadiene (DCPD) epoxy resin, phosphorus-containing epoxy resin, p-xylene epoxy resin, naphthalene epoxy resin (such as naphthol epoxy resin), benzofuran epoxy resin, isocyanate-modified epoxy resin, or a combination thereof, but the present application is not limited thereto.

The novolac epoxy resin may be phenol novolac epoxy resin, bisphenol A novolac epoxy resin, bisphenol F novolac epoxy resin, biphenyl novolac epoxy resin, phenol benzaldehyde epoxy resin, phenol aralkyl novolac epoxy resin, o-cresol novolac epoxy resin, or a combination thereof.

The phosphorus-containing epoxy resin may be DOPO (9,10-dihydro-9-oxa-10-phosphaphenanthrene 10-oxide) epoxy resin, DOPO-HQ epoxy resin, or a combination thereof. The aforementioned DOPO epoxy resin may be selected from one or more of DOPO-containing phenolic novolac epoxy resin, DOPO-containing cresol novolac epoxy resin, and DOPO-containing bisphenol-A novolac epoxy resin. The aforementioned DOPO-HQ epoxy resin may be selected from at least one of DOPO-HQ-containing phenolic novolac epoxy resin, DOPO-HQ-containing cresol novolac epoxy resin, and DOPO-HQ-containing bisphenol-A novolac epoxy resin.

In some exemplary embodiments, the resin composition comprises a phenolic resin. The phenolic resin may be a single-functional phenolic resin, a polyfunctional phenolic resin, or a combination thereof, but the present application is not limited thereto. The phenolic resin may comprise a phenoxy resin, a novolac resin, or a combination thereof, but the present application is not limited thereto.

In some exemplary embodiments, the resin composition comprises a benzoxazine resin. The benzoxazine resin may comprise bisphenol A benzoxazine resin, bisphenol F benzoxazine resin, phenolphthalein benzoxazine resin, dicyclopentadiene benzoxazine resin, phosphorus-containing benzoxazine resin, diamine benzoxazine resin, vinyl or allyl modified benzoxazine resin, or a combination thereof, but the present application is not limited thereto. Examples of the benzoxazine resin comprise those produced by Huntsman under the trade names of LZ-8270 (phenolphthalein benzoxazine resin), LZ-8280 (bisphenol F benzoxazine resin), or LZ-8290 (bisphenol A benzoxazine resin), or that produced by Showa High Polymer Co., Ltd under the trade name of HFB-2006M. The diamine benzoxazine resin may be diaminodiphenylmethane benzoxazine resin, diaminodiphenyl ether benzoxazine resin, diaminodiphenyl sulfone benzoxazine resin, diaminodiphenyl sulfide benzoxazine resin, or a combination thereof.

In some exemplary embodiments, the resin composition comprises a cyanate ester resin. The cyanate ester resin may be various types of cyanate ester resin known in the art. The cyanate ester resin may comprise cyanate ester resins with an Ar—O—C═N structure (wherein Ar is aryl, such as phenyl, naphthyl, or anthryl), but the present application is not limited thereto. The cyanate ester resin may comprise phenolic novolac cyanate ester resin, bisphenol A cyanate ester resin, bisphenol A novolac cyanate ester resin, bisphenol F cyanate ester resin, bisphenol F novolac cyanate ester resin, cyanate ester resin containing a dicyclopentadiene structure, cyanate ester resin containing a naphthalene ring structure, phenolphthalein cyanate ester resin, or a combination thereof, but the present application is not limited thereto. The cyanate ester resin may comprise cyanate ester resins produced by Lonza under the trade names of Primaset PT-15, PT-30S, PT-60S, BA-200, BA-230S, BA-3000S, BTP-2500, BTP-6020S, DT-4000, DT-7000, ULL950S, HTL-300, CE-320, LVT-50, LeCy etc., or a combination thereof, but the present application is not limited thereto.

In some exemplary embodiments, the resin composition comprises a polyester resin. The polyester resin is formed by esterification of an aromatic compound with a dicarboxylic acid group and an aromatic compound with a dihydroxy group. The polyester resin may be HPC-8000, HPC-8150, or HPC-8200 purchased from DaiNippon Ink Chemicals, or a combination thereof, but the present application is not limited thereto.

In some exemplary embodiments, the resin composition comprises a polyamide resin. The polyamide resin may be various types of polyamide resins known in the art, comprising various commercially available polyamide resin products, but the present application is not limited thereto.

In some exemplary embodiments, the resin composition comprises a polyimide resin. The polyimide resin may be various types of polyimide resins known in the art, comprising various commercially available polyimide resin products, but the present application is not limited thereto.

In some exemplary embodiments, the resin composition further comprises at least one of amine curing agents, flame retardants, inorganic fillers, curing accelerators, polymerization inhibitors, dyeing agents, solvents, toughening agents, and silane coupling agents.

In some exemplary embodiments, the resin composition comprises an amine curing agent. The amine curing agent may comprise dicyandiamide, diaminodiphenyl sulfone, diaminodiphenylmethane, diaminodiphenyl ether, diaminodiphenyl sulfide, or a combination thereof, but the present application is not limited thereto.

In some exemplary embodiments, the resin composition comprises a flame retardant. The flame retardant may be any one or more flame retardants used for preparing a prepreg, a resin film, a laminate, a printed circuit board, or a cured insulator.

The flame retardant may be a phosphorus-containing flame retardant. The flame retardant may be ammonium polyphosphate, hydroquinone bis-(diphenylphosphate), bisphenol A bis(diphenylphosphate), tris(2-carboxyethyl) phosphine (TCEP), tris(chloroisopropyl) phosphate, trimethyl phosphate (TMP), dimethyl methyl phosphonate (DMMP), resorcinol bis(dixylenyl phosphate) (RDXP, commercially available products such as PX-200, PX-201, PX-202, etc.), phosphazene (commercially available products such as SPB-100, SPH-100, SPV-100 etc.), melamine polyphosphate, DOPO and derivatives or resins thereof, diphenylphosphine oxide (DPPO) and derivatives or resins thereof, melamine cyanurate, tri-hydroxy ethyl isocyanurate, aluminum phosphinate (products such as OP-930, OP-935, etc.), or a combination thereof, but the present application is not limited thereto.

The flame retardant may be a DPPO compound (such as a bis-DPPO compound), a DOPO compound (such as a bis-DOPO compound), a DOPO resin (such as DOPO-HQ, DOPO-NQ, DOPO-PN, or DOPO-BPN), a DOPO-bonded epoxy resin, or a combination thereof, but the present application is not limited thereto, wherein, the DOPO-PN is a DOPO phenolic novolac compound, and the DOPO-BPN may be a bisphenolic novolac compound such as DOPO-BPAN (DOPO-bisphenol A novolac), DOPO-BPFN (DOPO-bisphenol F novolac), or DOPO-BPSN (DOPO-bisphenol S novolac).

In some exemplary embodiments, the resin composition comprises an inorganic filler. The inorganic filler may be anyone or more fillers used for preparing a resin film, a prepreg, a laminate, a printed circuit board, or a cured insulator. The inorganic filler may be silicon dioxide (fused, non-fused, porous, or hollow), aluminum oxide, aluminum hydroxide, magnesium oxide, magnesium hydroxide, calcium carbonate, aluminum nitride, boron nitride, aluminum silicon carbide, silicon carbide, titanium dioxide, zinc oxide, zirconium oxide, mica, boehmite (AlOOH), calcined talc, talc, silicon nitride, calcined kaolin, or a combination thereof, but the present application is not limited thereto. The inorganic filler may be spherical, fibrous, plate-like, particulate, flake-like or whisker-like. The inorganic filler may be pre-treated with a silane coupling agent (especially a vinyl silane coupling agent). The inorganic filler may be spherical silica treated with the vinyl silane coupling agent on its surface.

The amount of the inorganic filler is not particularly limited. In some exemplary embodiments, based on 100 parts by weight of total solid resins (excluding solvents and inorganic fillers) in the resin composition, the resin composition may contain 30 to 130 parts by weight of inorganic fillers. In some exemplary embodiments, the resin composition may preferably contain 40 to 110 parts by weight of inorganic fillers. In some exemplary embodiments, the weight ratio of the maleimide resin to the inorganic filler may be 1:0.5 to 1:2.5, and more preferably 1:0.8 to 1:1.5.

In some exemplary embodiments, the resin composition comprises a curing accelerator. The curing accelerator may comprise catalysts such as Lewis base and Lewis acid. The Lewis base may comprise imidazole, boron trifluoride amine complex, ethyltriphenyl phosphonium chloride, 2-methylimidazole (2MI), 2-phenyl-1H-imidazole (2PZ), 2-ethyl-4-methylimidazole (2E4M1), triphenylphosphine (TPP), 4-dimethylaminopyridine (DMAP), or a combination thereof, but the present application is not limited thereto. The Lewis acid may comprise metal salt compounds, such as manganese salts, iron salts, cobalt salts, nickel salts, copper salts, and zinc salts, in particular metal catalysts such as zinc octanoate and cobalt octanoate, but the present application is not limited thereto. The curing accelerator may comprise a curing initiator. The curing initiator may comprise peroxides that can generate free radicals. The curing initiator comprises 2,3-dimethyl-2,3-diphenylbutane, diisopropylbenzene peroxide, tert-butyl peroxybenzoate, tert-butyl peroxyisopropylmonocarbonate, dibenzoyl peroxide (BPO), 2,5-dimethyl-2,5-di(tert-butylperoxy)-3-hexyne (25B), bis(tert-butylperoxy isopropyl)benzene, azobisisobutyronitrile, or a combination thereof, but the present application is not limited thereto.

In some exemplary embodiments, the resin composition comprises a polymerization inhibitor. The polymerization inhibitor may be various types of polymerization inhibitors known in the art, comprising various commercially available polymerization inhibitor products, but the present application is not limited thereto. The polymerization inhibitor may comprise 1,1-diphenyl-2-trinitrophenylhydrazine, methacrylonitrile, dithioester, nitrogen oxygen stable free radical, triphenylmethyl free radical, metal ion free radical, sulfur free radical, hydroquinone, p-methoxyphenol, p-benzoquinone, phenothiazine, P-phenylnaphthylamine, p-tert-butylcatechol, methylene blue, 4,4′-methylenebis(6-tert-butyl-3-methylphenol), 2,2′-methylenebis(4-ethyl-6-tert-butylphenol), or a combination thereof, but the present application is not limited thereto. The polymerization inhibitor may comprise or consist of a nitrogen oxygen stable free radical. The nitrogen oxygen stable free radical may comprise a 2,2,6,6-tetrasubstituent piperidine-1-oxygen free radical, a 2,2,5,5-tetrasubstituent pyrrolidine-1-oxygen free radical, etc. from cyclic hydroxylamines, or a combination thereof, but the present application is not limited thereto. The “substituent” here refers to alkyl with a carbon number of 4 or less, such as methyl, ethyl, propyl, or butyl, especially methyl or ethyl. The nitrogen oxygen stable free radical may be 2,2,6,6-tetramethylpiperidin-1-oxygen free radical, 2,2,6,6-tetraethylpiperidin-1-oxygen free radical, 2,2,6,6-tetramethyl-4-oxopiperidin-1-oxyl, 2,2,5,5-tetramethylpyrrolidin-1-oxyl, 1,1,3,3-tetramethylisoindolin-2-oxyl, N,N-di-tert-butylamineoxyl, or a combination thereof, but the present application is not limited thereto. A stable free radical such as galvinoxyl may be used instead of the nitrogen oxygen free radical. The polymerization inhibitor may alternatively be a product derived from the substitution of hydrogen atoms or atomic groups in the aforementioned polymerization inhibitor by other atoms or atomic groups, such as products derived from the substitution of hydrogen atoms in the polymerization inhibitor by atomic groups such as amino, hydroxyl, or ketone carbonyl.

In some exemplary embodiments, the resin composition comprises a dyeing agent. The dyeing agent may comprise a dye or a pigment, but the present application is not limited thereto.

In some exemplary embodiments, the resin composition comprises a solvent. The solvent can change the solid content of the resin composition and adjust the viscosity of the resin composition. The solvent may comprise methanol, ethanol, ethylene glycol monomethyl ether, acetone, butanone (a.k.a. methyl ethyl ketone), methyl isobutyl ketone, cyclohexanone, toluene, xylene, methoxyethyl acetate, ethoxyethyl acetate, propoxyethyl acetate, ethyl acetate, dimethylformamide, dimethylacetamide, propylene glycol methyl ether, or a combination thereof, but the present application is not limited thereto. The solvent added to the resin composition can evaporate during the processing of the resin composition into a prepreg or resin film, so that the insulating layer of the prepreg or resin film contains no solvent or only a trace amount of solvent less than or equal to 3 wt % (i.e. 3% by weight). Therefore, the presence or absence of the solvent in the resin composition does not affect the characteristics of the product.

In some exemplary embodiments, the resin composition comprises a toughening agent. The toughening agent can improve the toughness of the resin composition. The toughening agent may comprise carboxyl-terminated butadiene acrylonitrile resin (CTBN), core-shell resin, or a combination thereof, but the present application is not limited thereto.

In some exemplary embodiments, the resin composition comprises a silane coupling agent. The silane coupling agent may comprise silane compounds, comprising siloxane, but the present application is not limited thereto. The silane coupling agent may comprise amino silane compounds, epoxide silane compounds, vinyl silane compounds, acrylate silane compounds, methacrylate silane compounds, hydroxysilane compounds, isocyanate silane compounds, methacryloyloxysilane compounds, acryloyloxysilane compounds, or a combination thereof, but the present application is not limited thereto.

### Products

In one aspect, the present application provides a product of which at least a portion is prepared from the resin composition. The product is used, for example, as a component in various electronic products, comprising a prepreg, a resin film, a laminate, a printed circuit board, or a cured insulator, but the present application is not limited thereto. In one aspect, the present application provides use of the resin composition of the present application in preparing a product. In one aspect, the present application provides use of the resin composition of the present application in preparing a prepreg, a resin film, a laminate, a printed circuit board, or a cured insulator. In one aspect, the present application provides a product, comprising a resin layer prepared from the resin composition. In one aspect, the present application provides a method for producing a product, comprising providing a resin layer prepared from the resin composition.

The product may comprise the resin composition in a semi-cured state (B-stage) or a cured state (C-stage). The product may comprise a resin layer, which is composition in the semi-cured state or the cured state. The product may comprise an insulating layer, which is the composition in the cured state.

In some exemplary embodiments, the present application provides a prepreg. The prepreg may comprise a reinforcing material and a semi-cured layer provided on the reinforcing material, wherein, the semi-cured layer is the resin composition in the semi-cured state. The semi-cured layer may be obtained by heating the resin composition to form the semi-cured state. In some exemplary embodiments, the present application provides a method for preparing a prepreg, comprising: providing the resin composition on a reinforcing material, and semi-curing the resin composition, in particular heating the resin composition, to form a prepreg comprising the reinforcing material and a semi-cured layer. Said providing the resin composition on the reinforcing material may comprise coating the resin composition on the reinforcing material. The heating may be baking heating. The heating may be heating to a semi-curing temperature. The semi-curing temperature of the resin composition in the present application may be 100° C. to 200° C. The reinforcing material may be a fiber material, a woven fabric, a non-woven fabric, or a combination thereof, but the present application is not limited thereto. The woven fabric may comprise a fiberglass fabric. The fiberglass fabric may be a commercially available fiberglass fabric that can be used for various printed circuit boards. The fiberglass fabric may be an E-type glass fabric, D-type glass fabric, S-type glass fabric, T-type glass fabric, L-type glass fabric, or Q-type glass fabric, wherein the type of fibers comprises yarns or roving or the like, and the form may comprise splitting or non-splitting, but the present application is not limited thereto. The woven fabric may comprise a liquid crystal resin woven fabric. The liquid crystal resin woven fabric may comprise a polyester woven fabric, a polyurethane woven fabric, or a combination thereof, but the present application is not limited thereto. The non-woven fabric may comprise a liquid crystal resin non-woven fabric. The liquid crystal resin non-woven fabric may comprise a polyester non-woven fabric, a polyurethane non-woven fabric, or a combination thereof, but the present application is not limited thereto. The reinforcing material may, for example, increase the mechanical strength of the prepreg. In some exemplary embodiments, the reinforcing material may also be pre-treated with the silane coupling agent.

In some exemplary embodiments, the present application provides a resin film. The resin film may comprise the resin composition in the semi-cured state. In one aspect, the present application provides a method for preparing a resin film, comprising semi-curing the resin composition, in particular heating the resin composition. The method for preparing the resin film may further comprise coating the resin composition on a substrate. In some exemplary embodiments, the present application provides a resin film combination, comprising a substrate and the resin film provided on the substrate. In one aspect, the present application provides a method for preparing a resin film combination, comprising providing a substrate and providing the resin film on the substrate. In some exemplary embodiments, said providing the resin film on the substrate comprises: coating the resin composition on the substrate, and semi-curing the resin composition, in particular heating the resin composition. The substrate may be a polyethylene terephthalate film (PET film), a polyimide film (PI film), a copper foil, a resin coated copper foil, or a combination thereof, but the present application is not limited thereto. The heating may be, for example, baking heating. The heating may be heating to a semi-curing temperature. The semi-curing temperature in the resin composition of the present application may be 100° C. to 200° C.

In some exemplary embodiments, the present application provides a laminate. The laminate may comprise at least two metal foils and an insulating layer provided between the metal foils. In some exemplary embodiments, the insulating layer separates the metal foils. The metal foil may comprise copper, aluminum, nickel, platinum, silver, gold, or an alloy thereof, especially a copper foil. The insulating layer may be obtained by heating and curing the aforementioned resin composition or resin composition in the semi-cured state. The heating may be, for example, baking heating. The heating and curing may be heating to a curing temperature. The curing temperature of the resin composition of the present application may be 180° C. to 250° C., in particular 210° C. to 240° C., and the curing time may be 80 to 180 minutes, in particular 100 to 150 minutes. The curing may further comprise applying pressure to the resin composition in the semi-cured state. The insulating layer may be formed (C-stage) by curing the aforementioned prepreg or resin film. The laminate may be, for example, a copper clad laminate (CCL).

The laminate may be further processed through a circuit preparation process to form a circuit board, such as a printed circuit board. A method for preparing a printed circuit board according to the present application may be as follows: first, a double-sided copper clad laminate (such as EM-890, purchased from Elite Material Co., Ltd.) having a specific thickness (such as 28 mils) and comprising 0.5 ounce (oz) HVLP (hyper very low profile) copper foils is drilled and electroplated, whereby electrical conduction is formed between the top copper foil and the bottom copper foil. Then, the top copper foil and the bottom copper foil are etched to form an inner-layer circuit. Next, the inner-layer circuit is subjected to browning treatment to form a concave-convex structure on its surface for increasing roughness. Thereafter, the copper foil, the prepreg, the inner-layer circuit board, the other prepreg, and the other copper foil are sequentially stacked and heated through a vacuum lamination apparatus at a temperature of 180° C. to 250° C. for 80 to 180 minutes to cure an insulating layer material of the prepregs. Finally, various circuit board processes known in the art, such as black oxide treatment, drilling, and copper plating, are performed on the outermost copper foil to obtain a printed circuit board.

In some exemplary embodiments, the present application provides a cured insulator. In some exemplary embodiments, the present application provides a method for preparing a cured insulator, comprising: curing the resin composition once or curing the resin composition through multiple curing processes. The multiple curing refers to greater than or equal to two times of curing. For example, the resin composition may be first semi-cured, in particular heated, to obtain the resin composition in the semi-cured state; and the resin composition in the semi-cured state is further cured, in particular heated. The cured insulator may comprise the resin composition in the cured state, the resin composition in the cured state containing a reinforcing material, or a combination thereof. The heating may be, for example, baking heating. In some exemplary embodiments, the resin composition in the semi-cured state is obtained by heating to a semi-curing temperature. The semi-curing temperature of the resin composition in the present application may be 100° C. to 200° C. In some exemplary embodiments, the resin composition is cured once or the resin composition in the semi-cured state is cured by heating to a curing temperature. The curing temperature of the resin composition of the present application may be 180° C. to 250° C., in particular 210° C. to 240° C., and the curing time may be 80 to 180 minutes, in particular 100 to 150 minutes. The curing may further comprise applying pressure to the resin composition or the resin composition in the semi-cured state.

The cured insulator may comprise the resin composition in the cured state. In some exemplary embodiments, the present application provides a method for preparing a cured insulator, comprising: curing the resin film, in particular heating the resin film. The method for preparing the cured insulator may further comprise coating the resin composition on a substrate and/or semi-curing the resin composition to form a resin film.

The cured insulator may comprise the resin composition in the cured state comprising a reinforcing material. In some exemplary embodiments, the present application provides a method for preparing a cured insulator, comprising: curing the prepreg, in particular heating the prepreg. The method for preparing the cured insulator may further comprise providing the resin composition on a reinforcing material, and semi-curing the resin composition, in particular heating the resin composition, to form a prepreg comprising the reinforcing material and a semi-cured layer.

The method for preparing the cured insulator may further comprise molding. For example, the resin composition or the resin composition in the semi-cured state may be placed into a mold, and molded and cured in the mold at a curing temperature and certain pressure, to obtain a cured insulator in a specific shape.

The cured insulator may be an insulating layer with no metal on the surface prepared by removing the surface metal foil from the aforementioned laminate or printed circuit board.

### Characteristics of the Products

In some exemplary embodiments of the present application, the product has at least one of the following characteristics:
the copper-free surface inner-layer circuit laminate is normal under the filling ability test, having no shadows or lacking resin;
the interface adhesion test between resin substrate and fiberglass fabric in the substrate observed with a scanning electron microscope is passed, having no gaps;
does not result in delamination under the heat resistance test after 5 hours of moisture absorption by the methods described in IPC-TM-650 2.6.16.1 and IPC-TM-650 2.4.23 (the heat resistance after 1 hour of moisture absorption does not result in delamination under test as required by industry specifications for laminates or printed circuit boards);
the glass transition temperature (DMA-Tg) measured by the method described in IPC-TM-650 2.4.24.4 is greater than or equal to 235° C., such as 235° C. to 290° C., 244° C. to 290° C., or 249° C. to 290° C.;
the copper foil peeling strength (P/S) measured by the method described in IPC-TM-650 2.4.8 is greater than or equal to 3.00 lb/in, such as 3.08 lb/in to 3.89 lb/in.

### EXAMPLES

The following examples are only used to illustrate the embodiments of the present application, but not to limit the present application.

### Raw Materials

The structures and sources of various raw materials used in the following examples are shown below:
X9-470: Indane-containing bismaleimide, purchased from DIC.
MIR-3000: Biphenylaralkyl type bismaleimide, purchased from Nippon Kayaku Co., Ltd.
BMI-5100: 3,3′-dimethyl-5,5′-diethyl-4,4′-diphenylmethane bismaleimide, purchased from Daiwakasei Industry Co., Ltd.
BMI-2300: Phenylmethane bismaleimide oligomer, purchased from Daiwakasei Industry Co., Ltd.
BMI-3000: Maleimide resin containing an aliphatic long chain structure, purchased from Designer Molecules INC.
Compound A1: Structure shown in formula (4), purchased from Wuhan Desytek Environmental Protection New Materials Co., Ltd.
Compound A2: Structure shown in formula (11), Synthesis Example 1.
Compound A3: Structure shown in formula (15), Synthesis Example 2.
Compound A4: Structure shown in formula (19), Synthesis Example 3.
Compound A5: Structure shown in formula (5), Synthesis Example 4.
Compound A6: Structure shown in formula (6), Synthesis Example 5.
Compound A7: Structure shown in formula (7), Synthesis Example 6.
SPB-100: Hexaphenoxycyclotriphosphazene, purchased from Otsuka Chemical Co., Ltd.
SPV-100: Allylphenoxyphosphonitrile, purchased from Otsuka Chemical Co., Ltd.
Di-DOPO: Double DOPO phosphorus-containing high melting point flame retardant, with a structure shown in formula (23), self-manufactured by referring to the method in Chinese Patent No. CN105936745A.

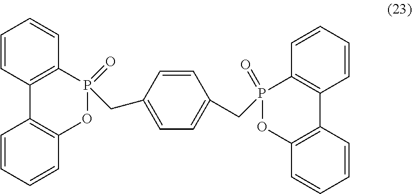 [SMILES: O=P1(Cc2ccc(CP3(=O)Oc4ccccc4-c4ccccc43)cc2)Oc2ccccc2-c2ccccc21]

PX-200: Resorcinol bis-(dimethylphenyl phosphate) (condensate), a.k.a. 1,3-phenylene tetra(2,6-dimethylphenyl) phosphate (condensate), purchased from Daihachi Chemical Industry Co., Ltd.
Hexa(4-vinylphenoxy)cyclophosphazene: purchased from Weihai Jinwei Chemical Co., Ltd.
Compound C1: Structure shown in formula (24), Synthesis Example 7.
4-vinylbenzocyclobutene: purchased from Chemtarget Technology Co., Ltd.
Benzocyclobutene: purchased from Aladdin.
SC-2500-SVJ: Spherical silica treated with a vinyl silane coupling agent on the surface, purchased from Admatechs.
2M1:2-methylimidazole, purchased from Shikoku Kasei.
Butanone: Commercially available, source not limited.
Dimethylacetamide (DMAC): commercially available from a variety of sources.

### Synthesis Example 1

250 mL of anhydrous tetrahydrofuran and 23.1 g of sodium metal were added into a three-necked flask and stirred at room temperature for 5 minutes; a solution of 120.1 g (1.00 mol) of 4-hydroxybenzocyclobutene dissolved in 250 mL of anhydrous tetrahydrofuran was added dropwise within 30 minutes, and the mixture was stirred at room temperature for 30 minutes to obtain a clear and transparent solution; a solution of 46.4 g (0.10 mol) of octachlorocyclotetraphosphonitrile dissolved in 250 ml of anhydrous tetrahydrofuran was added dropwise within 15 minutes, and then the mixture was further stirred at room temperature for 1 hour after addition. The mixture was heated to 60° C. and stirred for 48 hours at this temperature; then the mixture was cooled to room temperature, stood, and filtered after sodium chloride precipitated, the filtrate was concentrated, and the concentrated filtrate was poured into a large beaker containing a large amount of deionized water and stood to crystallize and precipitate a product; filtering was performed again to obtain a crude product; finally, the crude product was recrystallized with a mixed solvent of tetrahydrofuran and n-heptane; and the recrystallized product was dried in vacuum at 60° C. for 5 hours to obtain a white powder solid, labeled as compound A2.

### Synthesis Example 2

300 mL of anhydrous tetrahydrofuran and 28.9 g of sodium metal were added into a three-necked flask and stirred at room temperature for 5 minutes; a solution of 150.1 g (1.25 mol) of 4-hydroxybenzocyclobutene dissolved in 300 mL of anhydrous tetrahydrofuran was added dropwise within 30 minutes, and the mixture was stirred at room temperature for 30 minutes to obtain a clear and transparent solution; a solution of 57.9 g (0.10 mol) of decachlorocyclophosphazene dissolved in 300 ml of anhydrous tetrahydrofuran was added dropwise within 15 minutes, and then the mixture was further stirred at room temperature for 1 hour after addition. The mixture was heated to 60° C. and stirred for 48 hours at this temperature; then the mixture was cooled to room temperature, stood, and filtered after sodium chloride precipitated, the filtrate was concentrated, and the concentrated filtrate was poured into a large beaker containing a large amount of deionized water and stood to crystallize and precipitate a product; filtering was performed again to obtain a crude product; finally, the crude product was recrystallized with a mixed solvent of tetrahydrofuran and n-heptane; and the recrystallized product was dried in vacuum at 60° C. for 5 hours to obtain a white powder solid, labeled as compound A3.

### Synthesis Example 3

350 mL of anhydrous tetrahydrofuran and 34.6 g of sodium metal were added into a three-necked flask and stirred at room temperature for 8 minutes; a solution of 180.2 g (1.50 mol) of 4-hydroxybenzocyclobutene dissolved in 350 mL of anhydrous tetrahydrofuran was added dropwise within 40 minutes, and the mixture was stirred at room temperature for 30 minutes to obtain a clear and transparent solution; a solution of 69.5 g (0.10 mol) of dodecachlorocyclohexaphosphazene dissolved in 400 ml of anhydrous tetrahydrofuran was added dropwise within 20 minutes, and then the mixture was further stirred at room temperature for 1 hour after addition. The mixture was heated to 70° C. and stirred for 40 hours at this temperature; then the mixture was cooled to room temperature, stood, and filtered after sodium chloride precipitated, the filtrate was concentrated, and the concentrated filtrate was poured into a large beaker containing a large amount of deionized water and stood to crystallize and precipitate a product; filtering was performed again to obtain a crude product; finally, the crude product was recrystallized with a mixed solvent of tetrahydrofuran and n-heptane; and the recrystallized product was dried in vacuum at 60° C. for 5 hours to obtain a white powder solid, labeled as compound A4.

### Synthesis Example 4

250 mL of anhydrous tetrahydrofuran and 23.1 g of sodium metal were added into a three-necked flask and stirred at room temperature for 5 minutes; a solution of 44.7 g (0.47 mol) of phenol dissolved in 120 mL of anhydrous tetrahydrofuran was added dropwise within 20 minutes, the mixture was stirred at room temperature for 30 minutes, a solution of 52.2 g (0.15 mol) of phosphonitrilic chloride trimer dissolved in 250 ml of anhydrous tetrahydrofuran was added dropwise within 15 minutes, the mixture was stirred at room temperature for 30 minutes and then heated to 60° C., and the mixture reacted for 40 hours while stirring; then a solution of 64.9 g (0.54 mol) 4-hydroxybenzocyclobutene dissolved in 130 mL of anhydrous tetrahydrofuran was slowly added dropwise, and the reaction continued at 60° C. for 48 hours while stirring; subsequently, the mixture was cooled to room temperature, stood, and filtered after sodium chloride precipitated, the filtrate was concentrated, and the concentrated filtrate was poured into a large beaker containing a large amount of deionized water and stood to crystallize and precipitate a product; filtering was performed again to obtain a crude product; and the crude product was purified through silica gel chromatography separation with a mixed solution of cyclohexane and ethyl acetate as a mobile phase (cyclohexane: ethyl acetate=(500:1)-(10:1)), to obtain a product, labeled as compound A5.

### Synthesis Example 5

250 mL of anhydrous tetrahydrofuran and 23.1 g of sodium metal were added into a three-necked flask and stirred at room temperature for 5 minutes; a solution of 42.5 g (0.32 mol) of 4-allylphenol dissolved in 100 mL of anhydrous tetrahydrofuran was added dropwise within 15 minutes, the mixture was stirred at room temperature for 30 minutes, a solution of 52.2 g (0.15 mol) of phosphonitrilic chloride trimer dissolved in 250 ml of anhydrous tetrahydrofuran was added dropwise within 15 minutes, the mixture was stirred at room temperature for 30 minutes and then heated to 60° C., and the mixture reacted for 40 hours while stirring; then a solution of 86.5 g (0.72 mol) 4-hydroxybenzocyclobutene dissolved in 180 mL of anhydrous tetrahydrofuran was slowly added dropwise, and the reaction continued at 60° C. for 48 hours while stirring; subsequently, the mixture was cooled to room temperature, stood, and filtered after sodium chloride precipitated, the filtrate was concentrated, and the concentrated filtrate was poured into a large beaker containing a large amount of deionized water and stood to crystallize and precipitate a product; filtering was performed again to obtain a crude product; and the crude product was purified through silica gel chromatography separation with a mixed solution of cyclohexane and ethyl acetate as a mobile phase (cyclohexane: ethyl acetate=(500:1)-(10:1)), to obtain a product, labeled as compound A6.

### Synthesis Example 6

250 mL of anhydrous tetrahydrofuran and 23.1 g of sodium metal were added into a three-necked flask and stirred at room temperature for 5 minutes; a solution of 19.3 g (0.16 mol) of 4-hydroxybenzaldehyde dissolved in 50 mL of anhydrous tetrahydrofuran was added dropwise within 15 minutes, the mixture was stirred at room temperature for 30 minutes, a solution of 52.2 g (0.15 mol) of phosphonitrilic chloride trimer dissolved in 250 ml of anhydrous tetrahydrofuran was added dropwise within 15 minutes, the mixture was stirred at room temperature for 30 minutes and then heated to 60° C., and the mixture reacted for 36 hours while stirring; then a solution of 108.1 g (0.88 mol) 4-hydroxybenzocyclobutene dissolved in 200 mL of anhydrous tetrahydrofuran was slowly added dropwise, and the reaction continued at 60° C. for 48 hours while stirring; subsequently, the mixture was cooled to room temperature, stood, and filtered after sodium chloride precipitated, and the filtrate was concentrated to obtain an intermediate.

55 g of dehydrated methyltriphenylphosphine bromide and 500 ml of 0.17 g/ml dehydrated tetrahydrofuran solution of the intermediate were added to a three-necked flask at room temperature and stirred, 17 g of potassium tert-butoxide was slowly added, the mixture reacted for 2 hours, then 100 g of calcium bromide was added, the mixture reacted for 24 hours while stirring, the reaction was quenched with water, the tetrahydrofuran in the system was removed by rotary evaporation, ethyl acetate was added to separate the solution, the oil phase was collected, the ethyl acetate was removed by rotary evaporation, and then purification was performed through silica gel chromatography separation with a mixed solution of cyclohexane and ethyl acetate as a mobile phase (cyclohexane: ethyl acetate=(500:1)-(10:1)), to obtain a product, labeled as compound A7.

### Synthesis Example 7

250 mL of anhydrous tetrahydrofuran and 23.1 g of sodium metal were added into a three-necked flask and stirred at room temperature for 5 minutes; a solution of 38.0 g (0.31 mol) of 4-hydroxybenzocyclobutene dissolved in 80 mL of anhydrous tetrahydrofuran was added dropwise within 15 minutes, the mixture was stirred at room temperature for 30 minutes, a solution of 52.2 g (0.15 mol) of phosphonitrilic chloride trimer dissolved in 250 ml of anhydrous tetrahydrofuran was added dropwise within 15 minutes, the mixture was stirred at room temperature for 30 minutes and then heated to 60° C., and the mixture reacted for 40 hours while stirring; then a solution of 96.6 g (0.72 mol) 4-allylphenol dissolved in 200 mL of anhydrous tetrahydrofuran was slowly added dropwise, and the reaction continued at 60° C. for 48 hours while stirring; subsequently, the mixture was cooled to room temperature, stood, and filtered after sodium chloride precipitated, the filtrate was concentrated, and the concentrated filtrate was poured into a large beaker containing a large amount of deionized water and stood to crystallize and precipitate a product; filtering was performed again to obtain a crude product; and the crude product was purified through silica gel chromatography separation with a mixed solution of cyclohexane and ethyl acetate as a mobile phase (cyclohexane: ethyl acetate=(500:1)-(10:1)), to obtain a product, labeled as compound C1, with a structure shown in formula (24),

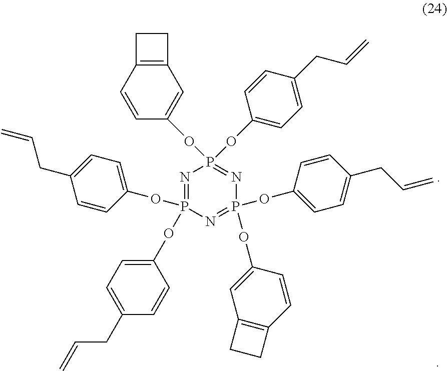 [SMILES: C=CCc1ccc(OP2(Oc3ccc(CC=C)cc3)=NP(Oc3ccc(CC=C)cc3)(Oc3ccc4c(c3)CC4)=NP(Oc3ccc(CC=C)cc3)(Oc3ccc4c(c3)CC4)=N2)cc1]

### Ingredients of Resin Compositions

Resin compositions in examples and comparative examples of the present application were prepared respectively according to the amounts in Table 1 and further prepared into various test samples or articles.

TABLE 1
Ingredients of resin compositions in examples and comparative examples (unit: parts
by weight)

| ingredients\examples | | E1 | E2 | E3 | E4 | E5 | E6 | E7 | E8 | E9 | E10 | E11 |
|---|---|---|---|---|---|---|---|---|---|---|---|---|
| maleimide resin | X9-470 | 100 | 100 | 100 | 100 | 100 | 100 | 100 | 100 | 100 | 40 | 60 |
| | MIR-3000 | | | | | | | | | | 30 | 20 |
| | BMI-5100 | | | | | | | | | | 10 | 10 |
| | BMI-2300 | | | | | | | | | | 15 | 5 |
| | BMI-3000 | | | | | | | | | | 5 | 5 |
| compound of formula (1) | compound A1 | 10 | 100 | 60 | | | | | | | 20 | |
| | compound A2 | | | | 60 | | | | | | 30 | 40 |
| | compound A3 | | | | | 60 | | | | | | 10 |
| | compound A4 | | | | | | 60 | | | | | 10 |
| | compound A5 | | | | | | | 60 | | | 5 | |
| | compound A6 | | | | | | | | 60 | | 10 | |
| | compound A7 | | | | | | | | | 60 | 15 | |
| Di-DOPO | | | | | | | | | | | 5 | 5 |
| PX-200 | | | | | | | | | | | 3 | 3 |
| inorganic filler | SC-2500-SVJ | 120 | 120 | 120 | 120 | 120 | 120 | 120 | 120 | 120 | 80 | 150 |
| curing accelerator | 2MI | 0.6 | 0.6 | 0.6 | 0.6 | 0.6 | 0.6 | 0.6 | 0.6 | 10.6 | 1.0 | 0.1 |
| solvent | butanone | q.s. | q.s. | q.s. | q.s. | q.s. | q.s. | q.s. | q.s. | q.s. | q.s. | q.s. |
| | DMAC | q.s. | q.s. | q.s. | q.s. | q.s. | q.s. | q.s. | q.s. | q.s. | q.s. | q.s. |

| Ingredients\comparative examples | | C1 | C2 | C3 | C4 | C5 | C6 | C7 | C8 | C9 | C10 |
|---|---|---|---|---|---|---|---|---|---|---|---|
| maleimide resin | X9-470 | 100 | 100 | 100 | 100 | 100 | 100 | 100 | 100 | 100 | 100 |
| compound of formula (1) | compound A1 | | 110 | | | | | | | | |
| SPB-100 | | | | 60 | | | | | | | |
| SPV-100 | | | | | 60 | | | | | | |
| Di-DOPO | | | | | | 60 | | | | | |
| PX-200 | | | | | | | 60 | | | | |
| hexa(4-vinylphenoxy)cyclophosphazene | | | | | | | | 60 | | | |
| compound C1 | | | | | | | | | 60 | | |
| 4-vinylbenzocyclobutene | | | | | | | | | | 60 | |
| benzocyclobutene | | | | | | | | | | | 60 |
| inorganic filler | SC-2500-SVJ | 120 | 120 | 120 | 120 | 120 | 120 | 120 | 120 | 120 | 120 |
| curing accelerator | 2MI | 0.6 | 0.6 | 0.6 | 0.6 | 0.6 | 0.6 | 0.6 | 0.6 | 0.6 | 0.6 |
| solvent | butanone | q.s. | q.s. | q.s. | q.s. | q.s. | q.s. | q.s. | q.s. | q.s. | q.s. |
| | DMAC | q.s. | q.s. | q.s. | q.s. | q.s. | q.s. | q.s. | q.s. | q.s. | q.s. |

The blanks in Table 1 represent “0”.

In Table 1, the addition amount of butanone or DMAC being “q.s.” represents the amount of a solvent that enables the solid resin in the resin composition to be completely dissolved. The “q.s.” also represents the total amount of the solvents to achieve a desired solid content of the entire resin composition, such as 70% by weight, but the present application is not limited thereto.

### Preparation of Resin Compositions and Products

Methods for preparing resin compositions in examples and comparative examples are as follows.

### Preparation of Varnish

Ingredients in each example or comparative example were added to a stirring tank according to the amounts in Table 1 and mixed uniformly to form a resin composition, referred to as a resin varnish.

Taking Example E1 as an example, 100 parts by weight of maleimide resin X9-470 was added to a stirrer containing an appropriate amount of butanone and DMAC, and stirred until solid ingredients were completely dissolved. Then, 10 parts by weight of compound A1 was added, and the mixture was continuously stirred until solid ingredients were completely dissolved. Next, 120 parts by weight of spherical silica SC-2500-SVJ was added and stirred until completely dispersed. Finally, 0.6 part by weight of 2M1 (dissolved into a solution through an appropriate amount of solvent) was added, and the mixture was stirred for 1 hour to obtain a varnish in Example E1.

In addition, varnishes in other examples and comparative examples were prepared according to the amounts of the ingredients listed in Table 1 and the method for preparing the varnish in Example E1.

### Preparation of Prepreg-1 (Using 2116 L-Fiberglass Fabric)

The resin composition varnish in each example or comparative example in Table 1 was passed through an impregnation tank in batches. A fiberglass fabric (such as L-fiberglass fabric with specification 2116) was passed through the impregnation tank so that the resin composition was attached to the fiberglass fabric, and was heated at 150° C.-160° C. to a semi-cured state (B-stage), to obtain prepreg-1 (resin content of about 52%).

### Preparation of Prepreg-2 (Using 1027 L-Fiberglass Fabric)

The resin composition varnish in each example or comparative example in Table 1 was passed through an impregnation tank in batches. A fiberglass fabric (such as L-fiberglass fabric with specification 1027) was passed through the impregnation tank so that the resin composition was attached to the fiberglass fabric, and was heated at 150° C.-160° C. to a semi-cured state (B-stage), to obtain prepreg-2 (resin content of about 71%).

### Preparation of Copper Clad Laminate-1 (by Laminating Eight Prepreg-1)

Two 12-micron thick very low profile copper foils (VLP copper foils) and eight prepreg-1 prepared from each resin composition in Table 1 were prepared in batches. A copper foil, eight prepreg-1, and a copper foil were stacked sequentially, and laminated in vacuum at 220° C. for 120 minutes to form the copper clad laminate-1. The eight stacked prepreg-1 were cured (C-stage) to form an insulating layer between two copper foils, with a resin content of about 52%.

### Preparation of Copper-Free Laminate-1 (by Laminating Eight Prepreg-1)

Copper foils on both sides of the copper clad laminate-1 were removed by etching to obtain copper-free laminate-1, formed by laminating eight prepreg-1, with a resin content of about 52%.

### Test and Characteristic Analysis of Products

### 1. Filling Ability Test

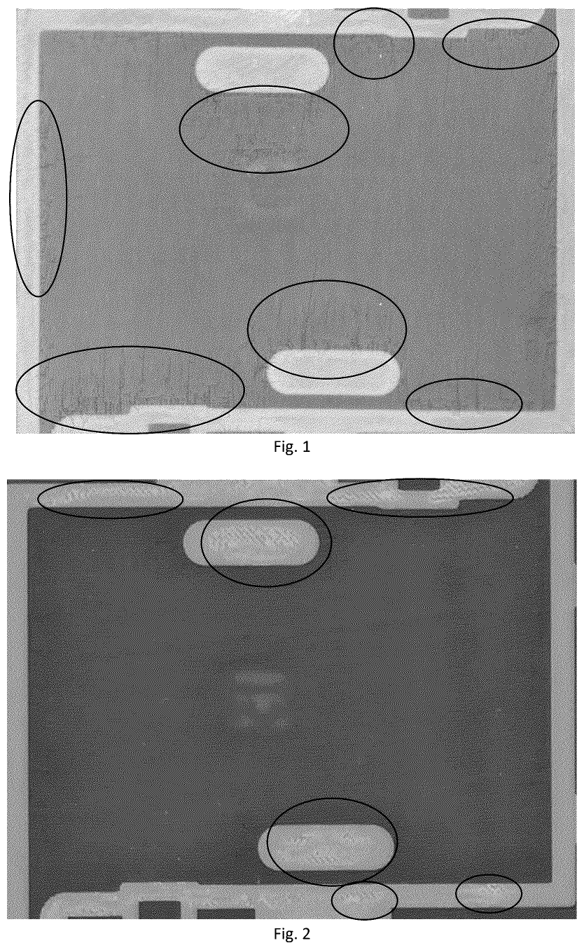

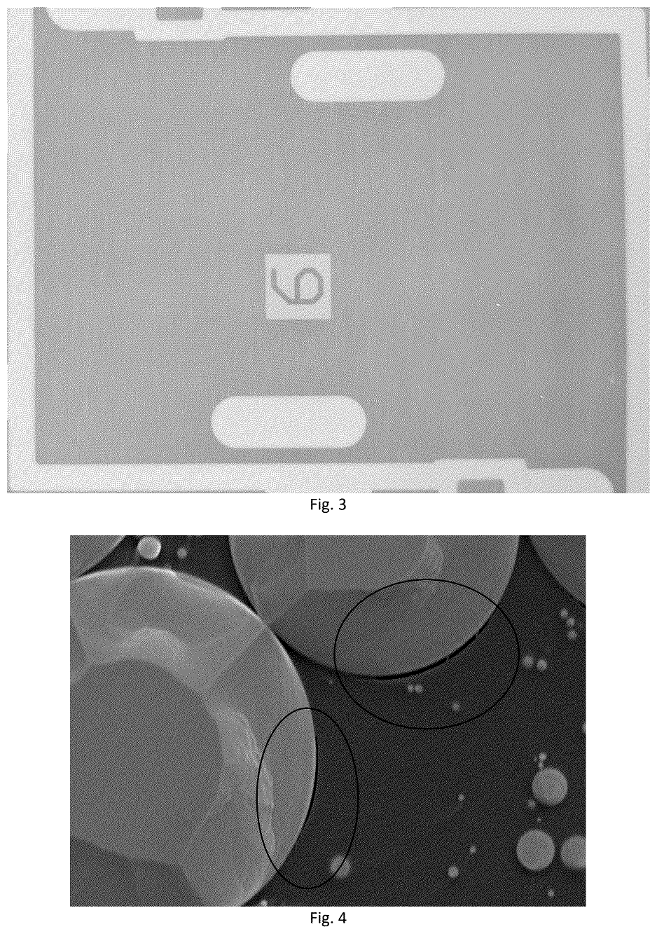

A 2.5 mil thick copper-containing laminate (such as product EM-827, available from Elite Electronic Material (Zhongshan) Co., Ltd.) was processed into a browned printed circuit board as an inner layer through a known browning treatment process, to evaluate the property of a prepreg in which resin flowed and filled in circuit areas or open areas between the circuit areas. One aforementioned prepreg-2 was stacked on each of two sides of a 2.5 mil thick browned printed circuit board, and then a very low profile copper foil (with a thickness of 18 microns) was stacked on each outer layer. In a vacuum press, they were pressed at 400 psi and 220° C. for 120 minutes to form an inner-layer circuit laminate containing copper on its surface. The copper foils on the outer layers were removed by etching to obtain an inner-layer circuit laminate with no copper on its surface. The above steps were repeated to prepare 15 copper-free inner-layer circuit laminates. The presence of shadows on the copper-free surfaces of the copper-free surface inner-layer circuit laminates was observed with an optical microscope. If there were shadows on the surface, it indicated poor filling ability, resulting in subsequent circuit board scrap. If at least one surface of the 15 copper-free inner-layer circuit laminate samples had shadows (as shown in FIG. 1, black circles represent dendritic stripes or uneven resin filling appearance), it was marked as “shadow”. If at least one surface of the 15 copper-free inner-layer circuit laminate samples lacked resin (as shown in FIG. 2, white areas in black circles), it was marked as “lack resin”. If the resin filling on the surfaces of the 15 copper-free inner-layer circuit laminate samples was normal and there were no shadows or resin lacked on the surfaces (as shown in FIG. 3), it was marked as “pass”, indicating excellent filling ability.

### 2. Interface Adhesion (Bonding Gap) Test

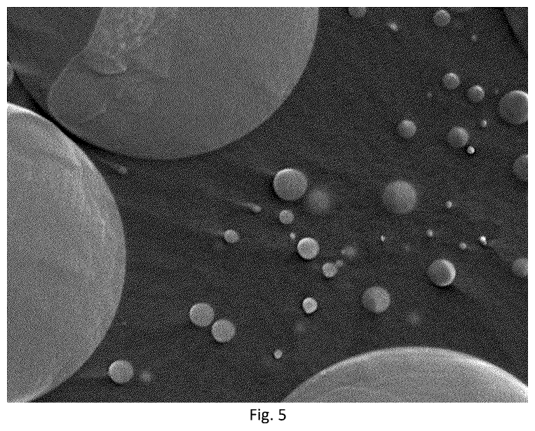

The aforementioned copper-free laminate-1 was used as a test sample. The test sample was cut into a 2.0 cm×1.5 cm rectangular sample from warp and filling directions respectively, and the strip samples were respectively cleaned with an ultrasonic cleaner for 1 minute. After ultrasonic cleaning twice, the strip samples were subjected to various slicing processes known in the art, such as gluing, grinding, polishing, cleaning, and gold plating, to produce qualified slices, which were then observed with a scanning electron microscopy (SEM). The presence of gaps between the resin substrate and the longitudinal or latitudinal fiberglass fabric in the sliced samples was sequentially observed at a magnification of 10000. If there were gaps, as shown in black circles in FIG. 4, it was marked as “NG”, indicating poor interface adhesion between resin substrate and fiberglass fabric, not passed. If there were no gaps, as shown in FIG. 5, it was marked as “pass”, indicating excellent interface adhesion between resin substrate and fiberglass fabric, the interface adhesion test passed.

3. Heat Resistance after Moisture Absorption (Pressure Cooking Test, PCT)

The aforementioned copper-free laminate-1 was used as a test sample. According to the method described in IPC-TM-650 2.6.16.1, the test sample absorbed moisture for 5 hours for pressure cooking test (PCT) (test temperature 121° C., relative humidity 100%). Then, according to the method described in IPC-TM-650 2.4.23, the test sample was immersed in a tin furnace at a constant temperature of 288° C. for 20 seconds and then taken out to observe whether a delamination occurs. For example, interlayer delamination or blistering occurs between insulating layers was considered as a delamination. Interlayer delamination or blistering may cause bubble separation between any layers of the substrate (visible to personnel). Delamination was marked as “NG”, and no delamination was marked as “pass”.

For example, according to the methods described in IPC-TM-650 2.6.16.1 and IPC-TM-650 2.4.23, the heat resistance of the product prepared from the resin composition of the present application after 5 hours of moisture absorption did not result in delamination under test (industry specifications for laminates or printed circuit boards require that their heat resistance after 1 hour of moisture absorption does not result in delamination under test).

### 4. Glass Transition Temperature (Tg) Test

The copper-free laminate-1 prepared through the resin composition in each aforementioned example or comparative example was used as a test sample for dynamic mechanical analysis (DMA). The sample was heated at a rate of 2° C. per minute within a temperature range of 35° C. to 330° C. According to the method described in IPC-TM-650 2.4.24.4, the glass transition temperature (in ° C.) of each test sample was measured.

In the art, the higher glass transition temperature, the better. A glass transition temperature difference greater than or equal to 5° C. indicates a significant difference in glass transition temperature between different substrates (indicating significant technical difficulties).

For example, according to the method described in IPC-TM-650 2.4.24.4, the glass transition temperature of the product prepared from the resin composition of the present application (DMA-Tg) was greater than or equal to 235° C.

### 5. Copper Foil Peeling Strength (P/S) Test

The copper clad laminate-1 prepared from the resin compositions of the aforementioned examples or comparative examples was cut into a rectangular sample having a width of 24 mm and a length of more than 60 mm, and the surface copper foil was etched, leaving only a strip-shaped copper foil having a width of 3.18 mm and a length of more than 60 mm. The force (in lb/in) required to pull the copper foil away from the surface of the laminate was measured using a universal tensile strength tester at a room temperature (about 25° C.) according to the method of IPC-TM-650 2.4.8.

In the art, the higher copper foil peeling strength, the better. A difference in copper foil peeling strength greater than or equal to 0.1 lb/in was considered a significant difference (indicating significant technical difficulties).

For example, for the product prepared from the resin composition of the present application, its copper foil peeling strength measured by the method described in IPC-TM-650 2.4.8 was greater than or equal to 3.00 lb/in, such as 3.08 lb/in to 3.89 lb/in.

The test and characteristic analysis results of the filling ability, interface adhesion between resin substrate and fiberglass fabric, heat resistance after moisture absorption, glass transition temperature, and copper foil peeling strength of the products prepared through the resin compositions in the examples and comparative examples of the present application are shown in Table 2.

TABLE 2
Test and characteristic analysis results of resin composition products in examples and
comparative examples

| characteristics | unit | E1 | E2 | E3 | E4 | E5 | E6 | E7 | E8 | E9 | E10 | E11 |
|---|---|---|---|---|---|---|---|---|---|---|---|---|
| filling ability | / | pass | pass | pass | pass | pass | pass | pass | pass | pass | pass | pass |
| interface adhesion | / | pass | pass | pass | pass | pass | pass | pass | pass | pass | pass | pass |
| PCT | / | pass | pass | pass | pass | pass | pass | pass | pass | pass | pass | pass |
| DMA-Tg | ° C. | 290 | 271 | 260 | 262 | 267 | 270 | 235 | 244 | 254 | 249 | 268 |
| P/S | lb/in | 3.89 | 3.08 | 3.60 | 3.65 | 3.68 | 3.70 | 3.45 | 3.39 | 3.54 | 3.55 | 3.48 |

| characteristics | unit | C1 | C2 | C3 | C4 | C5 | C6 | C7 | C8 | C9 | C10 |
|---|---|---|---|---|---|---|---|---|---|---|---|
| filling ability | / | pass | shadow | shadow | shadow | shadow | shadow | lack resin | shadow | lack resin | shadow |
| interface adhesion | / | NG | pass | pass | pass | NG | NG | pass | pass | pass | pass |
| PCT | / | NG | Pass | NG | NG | NG | NG | pass | pass | pass | NG |
| DMA-Tg | ° C. | 210 | 269 | 205 | 219 | 213 | 190 | 224 | 225 | 220 | 206 |
| P/S | lb/in | 2.80 | 2.65 | 2.30 | 2.57 | 1.90 | 2.00 | 2.70 | 2.89 | 2.50 | 2.38 |

According to the test results in Table 2, the following phenomena may be observed:
By comparing Examples E1-E3 with Comparative Examples C1-C2, it can be confirmed that, by the resin composition of the present application comprising 100 parts by weight of a maleimide resin and 10-100 parts by weight of the compound of formula (1), compared with resin compositions beyond the amount ranges, the products prepared in the present application had at least one of an improvement on filling ability, an improvement on interface adhesion between resin substrate and fiberglass fabric, an improvement on heat resistance after moisture absorption, an improvement on glass transition temperature, and an improvement on copper foil peeling strength.
By comparing Examples E3 and E7-E9 with Comparative Examples C3-C4 and C7-C8, it can be confirmed that, by the resin composition of the present application comprising a maleimide resin and the compound of formula (1), compared with resin compositions comprising phosphazene compounds other than the compound of formula (1), the products prepared in the present application had at least one of an improvement on filling ability, an improvement on heat resistance after moisture absorption, an improvement on glass transition temperature, and an improvement on copper foil peeling strength.
By comparing Examples E3-E9 with Comparative Examples C5-C6, it can be confirmed that, by the resin composition of the present application comprising a maleimide resin and the compound of formula (1), compared with resin compositions comprising additive flame retardants (flame retardants with no reactive functional groups) (other phosphorus-containing flame retardants other than phosphazenes), the products prepared in the present application had at least one of an improvement on filling ability, an improvement on interface adhesion between resin substrate and fiberglass fabric, an improvement on heat resistance after moisture absorption, an improvement on glass transition temperature, and an improvement on copper foil peeling strength.
By comparing Examples E3-E9 with Comparative Examples C9-C10, it can be confirmed that, by the resin composition of the present application comprising a maleimide resin and the compound of formula (1), compared with resin compositions comprising 4-vinylbenzocyclobutene or benzocyclobutene, the products prepared in the present application had at least one of an improvement on filling ability, an improvement on heat resistance after moisture absorption, an improvement on glass transition temperature, and an improvement on copper foil peeling strength.
By comparing Examples E1-E11 with Comparative Examples C1-C10, it can be confirmed that, by the resin composition of the present application comprising 100 parts by weight of a maleimide resin and 10-100 parts by weight of the compound of formula (1), the laminate prepared in the present application can achieve the technical effects of copper foil peeling strength greater than or equal to 3.00 lb/in or achieve filling ability test passed and glass transition temperature greater than or equal to 235° C. simultaneously; in contrast, Comparative Examples C1 to C10 without adopting the technical solution of the present application cannot achieve the aforementioned technical effects simultaneously.

What is claimed is:

1. A resin composition, characterized by comprising 100 parts by weight of a maleimide resin and 10 to 100 parts by weight of a compound of formula (1), 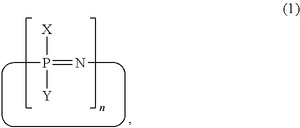
wherein n is an integer from 3 to 6, X and Y are each independently arylcyclobutenoxy or aryloxy, the number of arylcyclobutenoxy is greater than or equal to 3, and the aryloxy contains or does not contain an alkenyl, an acrylate group or a methacrylate group having 1 to 4 carbon atoms.

2. The resin composition according to claim 1, wherein
the maleimide resin comprises 4,4′-diphenylmethane bismaleimide, phenylmethane bismaleimide oligomer, biphenylaralkyl type bismaleimide, indane-containing bismaleimide, m-phenylene bismaleimide, bisphenol A diphenyl ether bismaleimide, 3,3′-dimethyl-5,5′-diethyl-4,4′-diphenylmethane bismaleimide, 4-methyl-1,3-phenylene bismaleimide, 1,6-bismaleimido(2,2,4-trimethyl)hexane, 2,3-dimethylphenylmaleimide, 2,6-dimethylphenylmaleimide, N-phenylmaleimide, maleimide resin containing an aliphatic long chain structure, or a combination thereof.

3. The resin composition according to claim 1, wherein the phosphorus content of the compound of formula (1) is 2.0 wt % to 13.0 wt %.

4. The resin composition according to claim 1, wherein an aryl in the arylcyclobutenoxy and the aryloxy is each independently substituted or unsubstituted phenyl, biphenyl, or naphthyl.

5. The resin composition according to claim 1, wherein
the structure of the arylcyclobutenoxy is shown in formula (2), and the structure of the aryloxy is shown in formula (3); 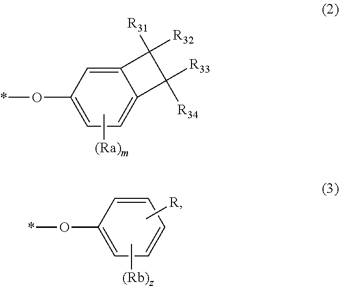
wherein, Ra and Rb are each independently H or alkyl having 1 to 4 carbon atoms, m is an integer from 0 to 3, z is an integer from 0 to 4, R is H or an alkenyl or an acrylate group or a methacrylate group having 1 to 4 carbon atoms, and R₃₁ to R₃₄ are each independently H or hydrocarbyl having 1 to 3 carbon atoms.

6. The resin composition according to claim 5, wherein R is a vinyl, a propenyl, an allyl, an acrylate group, or a methacrylate group.

7. The resin composition according to claim 1, wherein the compound of formula (1) has the following structure or a combination thereof:

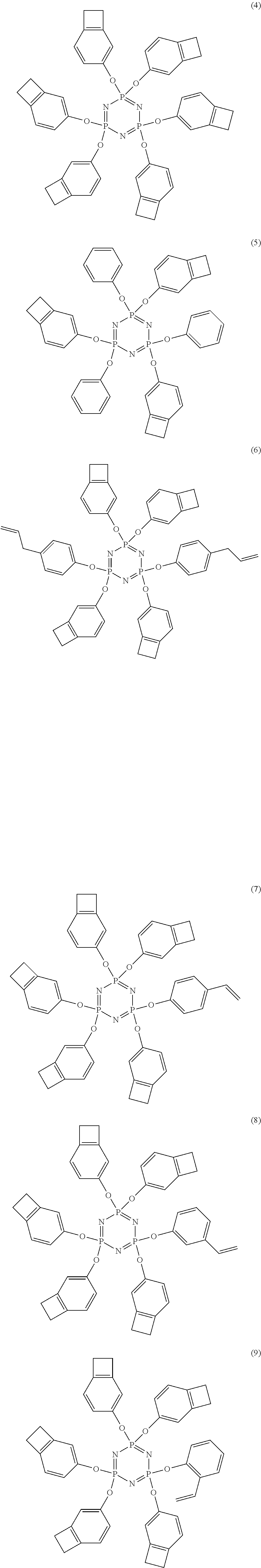

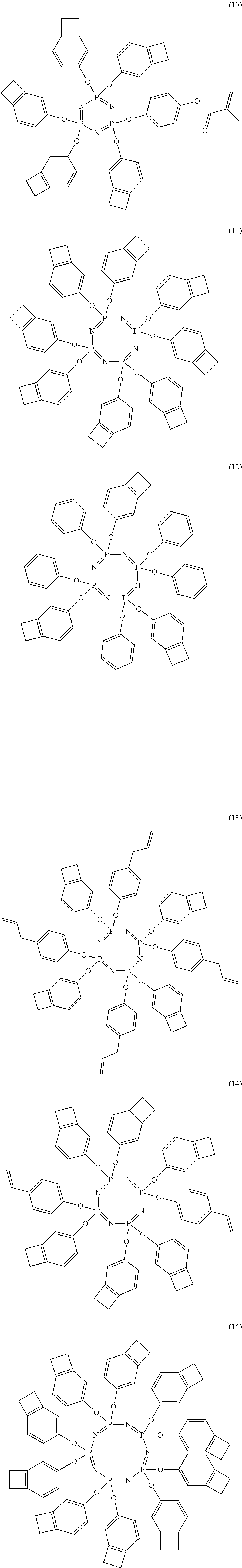

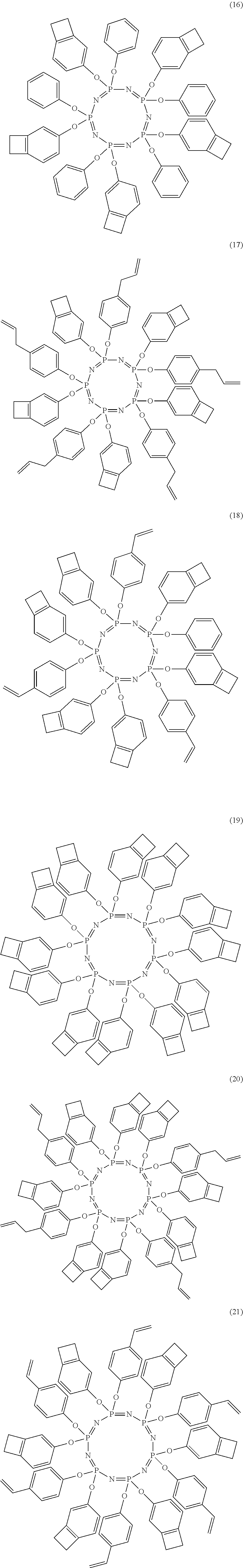

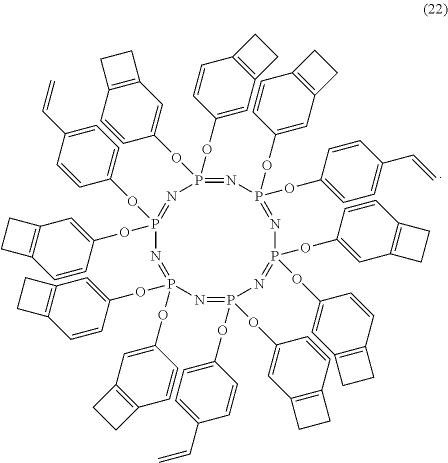 [SMILES: C=Cc1ccc(OP2(Oc3ccc4c(c3)CC4)=NP(Oc3ccc4c(c3)CC4)(Oc3ccc4c(c3)CC4)=NP(Oc3ccc(C=C)cc3)(Oc3ccc4c(c3)CC4)=NP(Oc3ccc4c(c3)CC4)(Oc3ccc4c(c3)CC4)=NP(Oc3ccc(C=C)cc3)(Oc3ccc4c(c3)CC4)=NP(Oc3ccc4c(c3)CC4)(Oc3ccc4c(c3)CC4)=N2)cc1]

8. The resin composition according to claim 1, wherein
the resin composition further comprises at least one of maleimide triazine resin, small molecular vinyl-containing resin, prepolymer of small molecular vinyl-containing resin, styrene maleic anhydride resin, epoxy resin, phenolic resin, benzoxazine resin, cyanate ester resin, polyester resin, polyamide resin, and polyimide resin.

9. The resin composition according to claim 1, wherein
the resin composition further comprises at least one of amine curing agents, flame retardants, inorganic fillers, curing accelerators, polymerization inhibitors, dyeing agents, solvents, toughening agents, and silane coupling agents.

10. A product, comprising a prepreg, a resin film, a laminate, a printed circuit board, or a cured insulator, wherein
at least a portion of the product is prepared from the resin composition according to claim 1.

11. The product according to claim 10, wherein the product has one, more, or all of the following characteristics:
a copper-free surface inner-layer circuit laminate is normal under the filling ability test;
the interface adhesion test between resin substrate and fiberglass fabric in the substrate observed with a scanning electron microscope is passed;
does not result in delamination under the heat resistance test after 5 hours of moisture absorption by the methods described in IPC-TM-650 2.6.16.1 and IPC-TM-650 2.4.23;
the glass transition temperature is greater than or equal to 235° C. as measured by the method described in IPC-TM-650 2.4.24.4; and
the copper foil peeling strength is greater than or equal to 3.00 lb/in as measured by the method described in IPC-TM-650 2.4.8.
